(19) United States
(12) Patent Application Publication
(10) Pub. No.: US 2026/0096300 A1
(43) Pub. Date: Apr. 2, 2026

(54) DISPLAY PANEL AND DISPLAY DEVICE

(71) Applicant: Hefei Visionox Technology Co., Ltd., Hefei (CN)

(72) Inventors: Zhiwei ZHOU, Hefei (CN); Hung-Chih YU, Hefei (CN); Jinfang ZHANG, Hefei (CN)

(73) Assignee: Hefei Visionox Technology Co., Ltd., Hefei (CN)

(21) Appl. No.: 19/412,143

(22) Filed: Dec. 8, 2025

Related U.S. Application Data
(63) Continuation of application No. PCT/CN2025/124626, filed on Sep. 26, 2025.

(30) Foreign Application Priority Data
Sep. 27, 2024 (CN) 202411366447.0
Jan. 22, 2025 (CN) 202510112902.2
Jan. 22, 2025 (CN) 202510112923.4
Mar. 17, 2025 (CN) 202510318449.0

(51) Int. Cl. H10K 59/122; H10K 59/124; H10K 59/131

(52) U.S. Cl. CPC H10K 59/122; H10K 59/124; H10K 59/131

(57) ABSTRACT

A display panel and an electronic device. The display panel includes: a substrate; an inorganic layer located on a side of the substrate and provided with a plurality of first openings penetrating through the inorganic layer along a thickness direction of the substrate; and an isolation structure located on a side of the inorganic layer away from the substrate, with a plurality of isolation openings being surrounded by the isolation structure, wherein orthographic projections of the plurality of first openings on the substrate are located at least partially within an orthographic projection of the isolation structure on the substrate.

### CROSS REFERENCE TO RELATED APPLICATIONS

The present application is a continuation application of International Application No. PCT/CN2025/124626, filed on Sep. 26, 2025, which claims priority to Chinese Patent Application No. 202411366447.0 titled “Display Panel and Display Device” filed on Sep. 27, 2024, Chinese Patent Application No. 202510318449.0 titled “Display Panel, Method for Preparing Display Panel and Electronic Device” filed on Mar. 17, 2025, Chinese Patent Application No. 202510112923.4 titled “Display Panel, Method for Preparing Display Panel and Electronic Device” filed on Jan. 22, 2025, and Chinese Patent Application No. 202510112902.2 titled “Display Panel, Method for Preparing Display Panel and Electronic Device” filed on Jan. 22, 2025. All of the aforementioned patent applications are hereby incorporated by reference in their entireties.

### TECHNICAL FIELD

The application relates to the field of display technology, particularly to a display panel and an electronic device.

### BACKGROUND

Organic Light-emitting Diodes (OLEDs) and flat display devices based on technologies such as LEDs are widely used in various consumer electronic products such as smartphones, televisions, laptops and desktop computers due to their advantages of high image quality, power saving, thin body and wide application range, etc., and have become the mainstream for display panels. In a traditional preparation process for a display panel, patterning of light-emitting pixels is usually achieved by using a fine metal mask (FMM). FMM technology is mature and has rich experience in mass production. However, FMM technology also has issues such as limited accuracy, high development cost and long development cycle. Technologies without using the fine metal mask eliminate limitations of traditional OLED processes on screen size, screen resolution and other screen performances, and have advantages of high performance, global size and agile delivery. Relevant contents about the technologies without using the fine metal mask are described in patent publications No. CN118251982A [symbol] CN115666161A [symbol] CN116648095A [symbol] CN117062489A [symbol] CN118678742A [symbol] CN 118785761A [symbol] CN115224220A [symbol] CN118678729A [symbol] CN118660529A [symbol] and CN118660589A, which are provided for reference.

However, there are still some issues with the display panel that urgently need to be addressed.

### SUMMARY

In order to overcome the technical problems mentioned in the above technical background, the embodiments of the application provide a display panel, including: a substrate; an inorganic layer located on a side of the substrate and provided with a plurality of first openings penetrating through the inorganic layer along a thickness direction of the substrate; and an isolation structure located on a side of the inorganic layer away from the substrate, with a plurality of isolation openings being surrounded by the isolation structure, wherein orthographic projections of the plurality of first openings on the substrate are located at least partially within an orthographic projection of the isolation structure on the substrate.

In some possible implementations, the application also provides a display panel comprising: a substrate; an inorganic layer located on a side of the substrate and provided with a plurality of first openings penetrating through the inorganic layer along a thickness direction of the substrate; and a pixel defining layer located on a side of the inorganic layer away from the substrate, with a plurality of pixel openings being surrounded by the pixel defining layer, wherein orthographic projections of the first openings on the substrate and orthographic projections of the pixel openings on the substrate are offset.

In some possible implementations, the present application also provides an electronic device comprising the display panel as described in the application.

Compared to existing technologies, the application has the following beneficial effects:
the display panel and the electronic device provided in the application can improve a pixel aperture ratio of the display panel and thus enhance a display effect of the display panel by setting the orthographic projections of the first openings on the substrate within the orthographic projection of the isolation structure on the substrate.

### BRIEF DESCRIPTION OF THE DRAWINGS

In order to provide a clearer explanation of technical solutions of the embodiments of the application, a brief introduction will be given below to the accompanying drawings required for the embodiments. It should be understood that the following drawings only illustrate certain embodiments of the application and should not be considered as limiting the scope. For those skilled in the art, other relevant drawings can be obtained based on these drawings without inventive efforts.

FIG. 1 is a first schematic partial top view of a display panel according to an embodiment of the application;

FIG. 2 is a first schematic cross-sectional view of FIG. 1 taken at A-A according to an embodiment of the application;

FIG. 3 is a second schematic cross-sectional view of FIG. 1 taken at A-A according to an embodiment of the application;

FIG. 4 is a second schematic partial top view of a display panel according to an embodiment of the application;

FIG. 5 is a schematic cross-sectional view of the display panel in FIG. 4 taken at B-B according to an embodiment of the application, ;

FIG. 6 is a third schematic partial top view of a display panel according to an embodiment of the application n;

FIG. 7 is a fourth schematic partial top view of a display panel according to an embodiment of the application;

FIG. 8 is a schematic cross-sectional view of the display panel in FIG. 7 taken at D-D according to an embodiment of the application, ;

FIG. 9 is a fifth schematic partial top view of a display panel according to an embodiment of the application;

FIG. 10 is a top view of a display panel according to an embodiment of the application;

FIG. 11 is a first schematic cross-sectional view of the display panel in FIG. 10 taken at C-C according to an embodiment of the application;

FIG. 12 is a second schematic cross-sectional view of the display panel in FIG. 10 at C-C according to an embodiment of the application ;

FIG. 13 is a sixth schematic partial top view of a display panel according to an embodiment of the application;

FIG. 14 is a schematic cross-sectional view of the display panel in FIG. 13 at E-E according to an embodiment of the application;

FIG. 15 is a first schematic top view of an inorganic layer of a display panel according to an embodiment of the application;

FIG. 16 is a second schematic top view of an inorganic layer of a display panel according to an embodiment of the application;

FIG. 17 is a third schematic top view of an inorganic layer of a display panel according to an embodiment of the application;

FIG. 18 is a third schematic cross-sectional view of FIG. 1 taken at A-A according to an embodiment of the application;

FIG. 19 is a fourth schematic cross-sectional view of FIG. 1 taken at A-A according to an embodiment of the application;

FIG. 20 is a seventh schematic partial top view of a display panel according to an embodiment of the application;

FIG. 21 is a first schematic cross-sectional view of a display panel including a encapsulation unit according to an embodiment of the application;

FIG. 22 is a second schematic cross-sectional view of a display panel including a encapsulation unit according to an embodiment of the application;

FIG. 23 is a first schematic cross-sectional view of a display panel including a second encapsulation layer and a third encapsulation layer according to an embodiment of the application;

FIG. 24 is a second schematic cross-sectional view of a display panel including a second encapsulation layer and a third encapsulation layer according to an embodiment of the application;

FIG. 25 is an eighth schematic partial top view of a display panel according to an embodiment of the application;

FIG. 26 is a schematic cross-sectional view of FIG. 12 taken at C-C according to an embodiment of the application.

Reference numerals: 1. Substrate; 2. Driver circuit layer; 3. Pixel defining layer; 31. Pixel opening; 32. Third via; 4. Isolation structure; 401. First isolation unit; 4011. Fifth edge; 402. Second isolation unit; 4021. Sixth edge; 403. Third isolation unit; 404. Fourth isolation unit; 405. Concave part; 41. First isolation part; 42. Second isolation part; 43. Third isolation part; 5. Insulation layer; 51. First via; 511. Third edge; 512. Fourth edge; 6. Inorganic layer; 61. First opening; 611. First edge; 612. Second edge; 613. Seventh Edge; 62. Second via; 63. Body part; 7. First electrode; 8. Light-emitting part; 9. Second electrode; 10. Light-emitting unit; 101. First light-emitting unit; 102. Second light-emitting unit; 103. Third light-emitting unit; 11. Isolation opening; 12. Encapsulation unit; 13. Second encapsulation layer; 14. Third encapsulation layer; 15. Pixel defining material layer; 16. Isolation material layer; 17. Signal trace; 171. Touch trace.

### DETAILED DESCRIPTION

In order to clarify purposes, technical solutions and advantages of the embodiments of the application, a clear and complete description of the technical solutions in the embodiments of the application will be provided below in conjunction with the accompanying drawings. Obviously, the described embodiments are only a portion of embodiments of the application, not all of embodiments of the application. Components in the embodiments of the application that are described and illustrated in the accompanying drawings can be arranged and designed in various different configurations.

Therefore, the detailed description of the embodiments of the application that are illustrated in the accompanying drawings is not intended to limit the scope of the application, but only to represent selected embodiments of the application. Other embodiments that can be obtained by those skilled in the art based on the embodiments of the application without inventive efforts are all within the scope of the application.

It should be noted that similar numerals and letters represent similar items in the following figures. Therefore, once an item is defined in one figure, it does not need to be further defined and explained in subsequent figures.

In the description of the application, it should be noted that directional or positional relationships indicated by the terms “center”, “up”, “down”, “vertical”, “horizontal”, “inside”, “outside”, etc. indicate directional or positional relationships as shown in the accompanying drawings, or directional or positional relationships commonly for a product of the application when it being used. They are provided only for convenience of describing the application and simplifying the description, and do not indicate or imply that the involved device or component must have such a specific orientation or must be constructed and operated in such a specific orientation. Therefore, they should not be understood as limitations on the application. In addition, the terms “first”, “second” and “third”, etc. are only used to distinguish descriptions and should not be understood as they indicating or implying relative importance.

It should be noted that different features in the embodiments of the application can be combined with each other without conflicts.

Improving density of light-emitting units (i.e. pixel density) in a display panel is an important way to enhance a display effect thereof. However, currently, a display panel that is made using the Fine Metal Mask (FMM) technology cannot further improve the density of light-emitting units due to limitations of the technology. After long-term researches, the inventor found that an isolation structure may be provided in some display panels to solve the technical problem of inability to further improve the density of light-emitting units. When an entire layer of a light-emitting functional layer and second electrodes are evaporated, the light-emitting functional layer and the second electrodes are separated by the isolation structure. Through multiple evaporation and etching processes (i.e. patterning of the light-emitting units), the light-emitting units of different colors can be formed in different isolation openings.

In related art, a display panel includes: a substrate; an insulation layer located on a side of the substrate; and a plurality of light-emitting units located on a side of the insulation layer away from the substrate, wherein the insulation layer includes an organic material, in which water vapor can easily transfer. Therefore, water vapor in the insulation layer can easily transfer to the light-emitting units, causing the light-emitting units to be inoperable and in turn generate dark spots, and accordingly affecting a display effect of the display panel.

In order to solve the technical problem mentioned above, the inventor inventively designed the following technical solutions. Specific implementations of the application will be described in detail below with reference to the accompanying drawings. It should be noted that the above-mentioned defects in the solution of the related art are founded by the inventors through practices and careful researches. Therefore, the process of finding the technical problem mentioned above as well as solutions proposed by the embodiments of the application for the problem in the following description are all contributions made by the inventors to the application in the process of proposing the application, and should not be understood as technical contents commonly known to those skilled in the art.

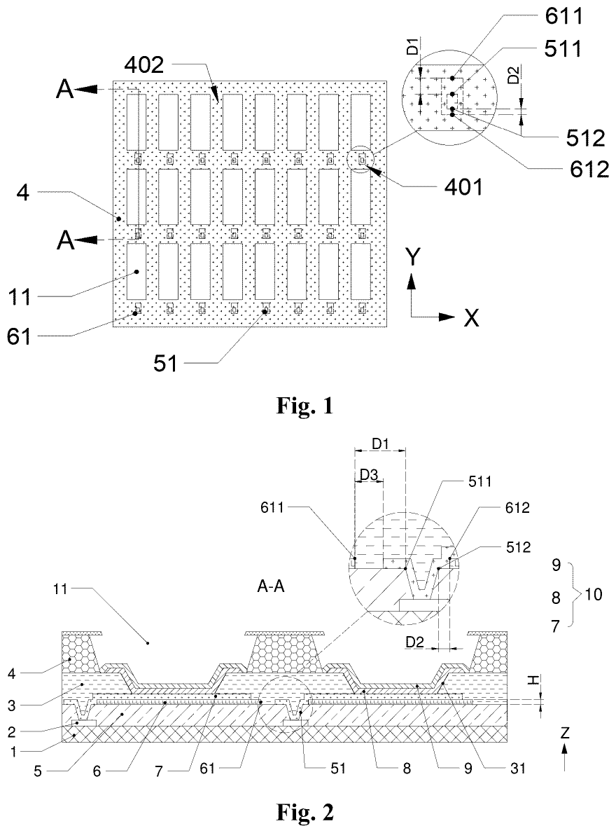

Referring to FIGS. 1 and 2, the embodiment provides a display panel, which includes: a substrate 1, an inorganic layer 6 and an isolation structure 4. The Inorganic layer 6 is located on a side of substrate 1 and is provided with a plurality of first openings 61 penetrating through the inorganic layer 6 along a thickness direction of the substrate 1. The isolation structure 4 is located on a side of the inorganic layer 6 away from the substrate 1, with a plurality of isolation openings 11 being surrounded by the isolation structure 4. Orthographic projections of the plurality of first openings 61 on the substrate 1 are located at least partially within an orthographic projection of the isolation structure 4 on the substrate 1.

The display panel according to the present application can improve a pixel aperture ratio of the display panel and thus enhance a display effect of the display panel by setting the orthographic projections of the first openings 61 on the substrate 1 within the orthographic projection of the isolation structure 4 on the substrate 1.

In some optional embodiments, as shown in FIGS. 1 and 2, the display panel may further includes a driver circuit layer 2, an insulation layer 5, and a plurality of light-emitting units 10. The driver circuit layer 2 is located on the substrate 1, the insulation layer 5 is located on a side of the driver circuit layer 2 away from the substrate 1, and the insulation layer 5 is provided with a plurality of first vias 51 penetrating through the insulation layer 5 along the thickness direction Z of the substrate 1.

The inorganic layer 6 is located on a side of the insulating layer 5 away from substrate 1. An orthographic projection of the inorganic layer 6 on the substrate 1 overlaps at least partially with an orthographic projection of the insulating layer 5 on the substrate 1. The inorganic layer 6 is provided with the first openings 61 penetrating through the inorganic layer 6 along the thickness direction Z of substrate 1.

The light-emitting units 10 are located at least partially within the isolation openings 11. Each of the light-emitting unit 10 includes a first electrode 7, and the first electrode is electrically connected to the driver circuit layer 2 through the first via 51.

The inorganic layer 6 plays a function of blocking water vapor. In the embodiment, the inorganic layer 6 is disposed between the light-emitting units 10 and the insulating layer 5. The inorganic layer 6 not only can block external water vapor from entering the insulating layer 5, but also can block the water vapor in the insulating layer 5 from entering a light-emitting material layer for the light-emitting units 10, thereby reducing a risk of dark spots appearing in the light-emitting units 10 due to the water vapor in the insulating layer 5 and improving the display effect of the display panel.

If the inorganic layer 6 completely covers the insulating layer 5, the water vapor in the insulating layer 5 would not be discharged during subsequent preparation processes of the display panel. When the water vapor in the insulating layer 5 reaches a certain amount, it is easy to cause the inorganic layer 6 to crack, thereby affecting stability of the inorganic layer 6 and accordingly affecting an effect of the inorganic layer 6 in blocking the water vapor in the insulating layer 5 from entering the light-emitting unit 10.

In this embodiment, since the inorganic layer 6 is provided with the first openings 61, the water vapor in the insulating layer 5 can be discharged timely during subsequent preparation processes of the display panel, so as not to easily cause the inorganic layer 6 to crack. Since the orthographic projection of the first opening 61 on the substrate 1 is located within the orthographic projection of the isolation structure 4 on the substrate 1, the vapor discharged from the first openings 61 cannot easily invade the light-emitting units 10, thus making it less likely for dark spots to appear in the light-emitting units 10.

In some embodiments, the orthographic projections of the first opening 61 on the substrate 1 and an orthographic projection of the first via 51 on the substrate are both located within the orthographic projection of the isolation structure 4 on the substrate between adjacent light-emitting units 10. In some possible implementations, as shown in FIGS. 4 and 5, the orthographic projection of the first opening 61 and the first via 51 on the substrate 1 are both located within the orthographic projection of a side of the isolation structure 4 facing the substrate 1 on the substrate 1.

In this way, the first opening 61 is less likely to affect flatness of the side of the isolation structure 4 facing the isolation opening 11, thereby improving an overlap effect between the second electrode 9 and the sidewall of the isolation structure 4, and accordingly further improving the display effect of the display panel.

In some embodiments, as shown in FIG. 5, a minimum one D4 of distances between edges of an orthographic projection of a side of the first opening 61 away from the substrate 1 on the substrate 1 and an edge of an orthographic projection of a sidewall of the isolation structure 4 facing the isolation opening 11 on a side of the sidewall close to the substrate 1 on the substrate 1 may be greater than 0 μm and less than or equal to 10 μm. For example, the distance D4 may be 1 μm, 2 μm, 3 μm, 4 μm, 5 μm, 6 μm, 7 μm, 8 μm, 9 μm, or 10 μm. Reasonably setting the distance D4 can further reduce impact of the first opening 61 on the flatness of the side of the isolation structure 4 facing the isolation opening 11, thereby improving the overlap effect of between the second electrode 9 and the sidewall of the isolation structure 4.

In this embodiment, the orthographic projections of the first opening 61 and the first via 51 on the substrate 1 are both located within the orthographic projection of the isolation structure 4 on the substrate 1 between adjacent light-emitting units 10. In this way, impact of the first opening 61 on an area of the isolation opening 11 can be reduced, thereby increasing a light-emitting area of the light-emitting unit 10, and improving a pixel aperture ratio of the display panel, and accordingly improving the display effect of the display panel.

Based on the above design, this embodiment can improve the pixel aperture ratio of the display panel and thus enhance the display effect of the display panel by setting the orthographic projections of the first opening 61 and the first via 51 on the substrate 1 within the orthographic projection of the isolation structure 4 on the substrate 1 between adjacent light-emitting units 10.

In some possible implementations, please refer to FIGS. 1 and 2 again, the light-emitting unit 10 may further includes a light emitting part 8 and a second electrode 9 which are located on a side of the first electrode 7 away from the substrate 1 and sequentially stacked along a direction Z away from the substrate 1.

For example, the display panel may further include a pixel defining layer 3 located between the inorganic layer 6 and the isolation structure 4. The pixel defining layer 3 includes a plurality of pixel openings 31, each of which communicates with the isolation opening 11 to expose a portion of the first electrode 7. For example, the pixel defining layer 3 may include an inorganic insulating material. For example, the inorganic layer 6 may be in contact with the first electrodes 7.

The provision of the isolation structure 4 enables it is possible for the display panel to form film layers of light-emitting units 10 of different colors in different isolation openings 11 without using a fine metal mask. When forming a light-emitting material layer, the light-emitting material layer will be separated by the isolation structure 4 to form a plurality of light-emitting parts 8 which are spaced apart from each other. When forming a material layer for the second electrodes 9, the material layer for the second electrodes 9 will be separated by the isolation structure 4 to form the second electrodes 9 which are spaced apart from each other. The isolation structure 4 includes a conductive material, and the second electrodes 9 are electrically connected to the isolation structure 4. One of the first electrodes 7, one of the light-emitting parts 8 and one of the second electrodes 9 form one of the light-emitting units 10. The first electrodes 7 may serve as an anode, and the second electrodes 9 may serve as a cathode.

In this way, different light-emitting units 10 can be made independent of each other, thereby reducing crosstalk between adjacent light-emitting units 10 and enhancing the display effect of the display panel. Moreover, due to presence of the isolation structure 4, the light-emitting material layer and the material layer for the second electrodes 9 in each color of the light-emitting units 10 in the display panel can be fully prepared first and then patterned, making it is possible to eliminate the fine metal mask, thereby saving manufacturing cost of the display panel.

In some embodiments, the orthographic projection of the first opening 61 on the substrate 1 and the orthographic projection of the pixel opening 31 on the substrate 1 are offset. That is, the first opening 61 does not extend to a position where the pixel opening 31 is located. Offsetting of the first opening 61 and the pixel opening 31 can reduce impact of the first opening 61 on light-emitting effect.

In some embodiments, the orthographic projection of the first via 51 on the substrate 1 is located within the orthographic projection of the first electrode 7 on the substrate 1, which enables more portions of the first electrode 7 to extend into the first via 51, facilitating electrical connection between the first electrode 7 and the driver circuit layer 2 through the first via 51, and improving connection yield between the first electrode 7 and the driver circuit layer 2.

In some possible implementations, please refer to FIGS. 1 and 2, the first via 51 communicates with the first opening 61, and the first electrode 7 is electrically connected to the driver circuit layer 2 through the first opening 61 and the first via 51.

In some embodiments, the orthographic projection of the first via 51 on the substrate 1 is located within the orthographic projection of the first opening 61 on the substrate 1.

In some embodiments, an area of the orthographic projection of the first via 51 on the substrate 1 is smaller than an area of the orthographic projection of the first opening 61 on the substrate 1.

In this embodiment, the first via 51 and the first opening 61 form a sleeve hole. Through the first opening 61, not only the first electrode 7 can be electrically connected to the driver circuit layer 2, but also the water vapor in the insulation layer 5 can be discharged timely. In addition, for a first via 51, there requires only one first opening 61 to be provided in the inorganic layer 6 to communicate with the first via 51 without need for providing other vias, which can simplify the structure of the inorganic layer 6 and facilitate preparation and molding of the inorganic layer 6.

In some possible implementations, please refer to FIGS. 1 and 2 again, the orthographic projection of the first opening 61 on the substrate 1 is located partially outside the orthographic projection of the first electrode 7 on the substrate 1. For example, a part of the orthographic projection of the first opening 61 on the substrate 1 is offset from the orthographic projection of the first electrode 7 on the substrate 1.

In this way, the first electrode 7 does not completely cover the first opening 61, and the water vapor in the insulation layer 5 can be discharged timely from the first opening 61 that is not covered by the first electrode 7. The orthographic projection of the first electrode 7 on the substrate 1 covers only a part of the orthographic projection of the first opening 61 on the substrate 1.

In some embodiments, please refer to FIGS. 1 and 2 again, a center of the orthographic projection of the first opening 61 on the substrate 1 is spaced apart from a center of the orthographic projection of the first via 51 on the substrate 1. In this way, the first opening 61 is offset from the first via 51, making it easier for the first electrode 7 not to completely cover the first opening 61.

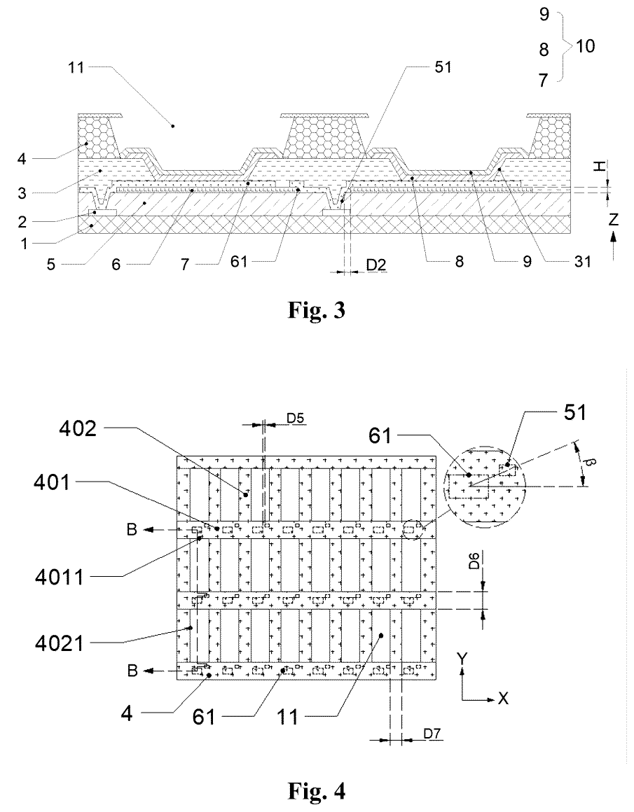

In some other optional embodiments, as shown in FIG. 3, the orthographic projection of the first opening 61 on the substrate 1 is located within the orthographic projection of the first electrode 7 on the substrate 1, and the orthographic projection of the first via 51 on the substrate 1 is located within the orthographic projection of the first electrode 7 on the substrate 1. That is, in this embodiment, unlike FIG. 2 where edges of the first electrode 7 are spaced apart from edges of a portions t of the first openings 61, the first electrode 7 covers both the first opening 61 and the first via 51, which can improve a distribution area of the first electrode 7 and ensure a connection yield between the first electrode 7 and the driver circuit layer 2.

In some embodiments, please refer to FIGS. 1 and 2 again, the orthographic projection of the first opening 61 on the substrate 1 includes a first edge 611 and a second edge 612 arranged opposite to each other. An orthographic projection of a side of the first via 51 away from the substrate 1 on the substrate 1 includes a third edge 511 and a fourth edge 512 arranged opposite to each other. The first edge 611, the third edge 511, the fourth edge 512 and the second edge 612 are arranged in the order. The third edge 511 is located on a side of the fourth edge 512 away from the light-emitting unit 10 that corresponds to the first via 51 where the third edge 511 and the fourth edge 512 are located. The light-emitting unit 10 that corresponds to the first via 51 is the light-emitting unit whose first electrode 7 is electrically connected to the driver circuit layer 2 through the first via 51.

In some embodiments, a minimum distance D1 between the first edge 611 and the third edge 511 is greater than a minimum distance D2 between the second edge 612 and the fourth edge 512. In this way, it makes easier that the first electrode 7 does not completely cover the first opening 61, so that the water vapor in the insulation layer 5 can be timely discharged from a space between the first edge 611 and a side of the first electrode 7 facing the first edge 611.

In some possible implementations, please refer to FIGS. 1 and 2 again, the minimum distance D1 between the first edge 611 and the third edge 511 may be greater than or equal to 2 μm and less than or equal to 10 μm. For example, the minimum distance D1 may be 2 μm, 3 μm, 4 μm, 5 μm, 6 μm, 7 μm, 8 μm, 9 μm, or 10 μm.

In some embodiments, the minimum distance D2 between the second edge 612 and the fourth edge 512 may be greater than or equal to 0.3 μm and less than or equal to 5 μm. For example, the minimum distance D2 may be 0.3 μm, 1 μm, 2 μm, 3 μm, 4 μm, 4.5 μm, or 5 μm.

Reasonably setting the minimum distance D1 and the minimum distance D2 can enable the water vapor in the insulation layer 5 to be discharged timely from the first opening 61, and moreover, the first electrode 7 to be electrically connected to the driver circuit layer 2 through the first opening 61.

In some possible implementations, as shown in FIG. 2, the first electrode 7 is spaced apart from the first edge 611. For example, the orthographic projection of the first electrode 7 on the substrate 1 overlaps with an orthographic projection of the second edge 612 on the substrate 1. For example, the orthographic projection of the first electrode 7 on the substrate 1 overlaps with the orthographic projection of the fourth edge 512 on the substrate 1. For example, the orthographic projection of the first electrode 7 on the substrate 1 overlaps with the orthographic projection of the third edge 511 on the substrate 1.

In some embodiments, the first edge 611 is located outside the orthographic projection of the first electrode 7 on the substrate 1.

In some embodiments, the third edge 511 is located within the orthographic projection of the first electrode 7 on the substrate 1.

In some embodiments, the first electrode 7 covers sidewalls of the first via 51.

In this embodiment, the first electrode 7 extends along one sidewall of the first via 51 to be electrically connected to the driver circuit layer 2, and then extends along the other sidewall of the first via 51 to a side of the insulating layer 5 away from the substrate 1. In this way, the first electrode 7 covers the second edge 612, the fourth edge 512, and the third edge 511. Since the first electrode 7 does not completely cover the first opening 61, the first electrode 7 does not cover the first edge 611.

In some embodiments, at least a portion of edges of the orthographic projection of the first electrode 7 on the substrate 1 is located within the orthographic projection of the first opening 61 of the substrate 1, so that the first electrode 7 can be electrically connected to the driver circuit layer 2 through the first opening 61 and the first via 51.

In some embodiments, a minimum distance D3 between an orthographic projection of a part of the first electrode 7 located in the first opening 61 on a side of the part facing the first edge 611 on the substrate 1 and the first edge 611 is greater than or equal to 2 μm and less than or equal to 8 μm. For example, the distance D3 may be 2 μm, 3 μm, 4 μm, 5 μm, 6 μm, 7 μm, or 8 μm. Reasonably setting the distance D3 can improve the effect of the insulation layer 5 in blocking the water vapor from entering the light-emitting unit 10 while the water vapor in the insulation layer 5 being timely discharged.

Another embodiment will be described below.

In some possible implementations, please refer to FIGS. 4 and 5, the first via 51 may be spaced apart from the first opening 61. That is, the first via 51 and the first opening 61 do not affect each other, which solves the problem of the water vapor spreading from the first opening 61 to the first electrode 7 through the first via 51, and further improving the yield of the display panel.

In some embodiments, the inorganic layer 6 may be provided with a plurality of second vias 62 penetrating through the inorganic layer 6. The first via 51 communicates with the second via 62, and the first electrode 7 is electrically connected to the driver circuit layer 2 sequentially through the second via 62 and the first via 51.

In some embodiments, the orthographic projection of the first electrode 7 on the substrate 1 is located outside the orthographic projection of the first opening 61 on the substrate 1.

In this embodiment, the first opening 61 is spaced apart from the first via 51, the first electrode 7 does not extend into the first opening 61, and the inorganic layer 6 includes the second via 62 which is spaced apart from the first opening 61. In this way, the water vapor in the insulating layer 5 can be discharged timely through the first opening 61, and such discharging of the water vapor from the first opening 61 is less likely to damage the first electrode 7, and preventing the inorganic layer 6 from cracking. The first electrode 7 can be electrically connected to the driver circuit layer 2 through the second via 62 and the first via 51.

In some embodiments, the orthographic projection of the first via 51 on the substrate 1 may overlap with an orthographic projection of the second via 62 on the substrate 1, so that the first electrode 7 can be electrically connected to the driver circuit layer 2 through the first via 51 and the second via 62.

In some embodiments, the orthographic projection of the first via 51 on the substrate 1 may be located within the orthographic projection of the second via 62 on the substrate 1. By making the size of the second via 62 large enough, the first via 51 and the second via 62 can form a sleeve hole, and the inorganic layer 6 does not block the part of the first electrode 7 inside the first via 5, which can improve connection yield between the first electrode 7 and the driver circuit layer 2.

In some embodiments, a center of the orthographic projection of the first via 51 on the substrate 1 coincides with a center of an orthographic projection of the second via 62 on the substrate 1. By making an interval between edges of the orthographic projection of the first via 51 on the substrate 1 to be equal to an interval of edges of the orthographic projection of the second via 62 on the substrate 1, the problem of causing some part of the first via 51 to fall outside the second via 62 due to errors can be reduced, thereby ensuring the connection yield between the first electrode 7 and the driver circuit layer 2.

In this way, it is more beneficial for the first electrode 7 to be electrically connected to the driver circuit layer 2 through the second via 62 and the first via 51.

In some possible implementations, please refer to FIGS. 4 and 5 again, the first via 51 and the first opening 61 are arranged along an extension direction of the isolation structure 4.

For example, the first via 51 and the first opening 61 are arranged along a circumference direction of the isolation opening 11.

Due to the arrangement of the first via 51 and the first opening 61 along the extension direction of the isolation structure 4 or the circumference direction of the isolation opening 11, a width of the isolation structure 4 at a location where the first via 51 and the first opening 61 are located can be reduced, which is more beneficial to increase an opening area of the isolation opening 11 and further improving the pixel aperture ratio of the display panel.

In some embodiments, as shown in FIGS. 4 and 5, for adjacent first via 51 and first opening 61, a minimum one D5 of distances between edges of the orthographic projection of the first via 51 on the substrate 1 and edges of the orthographic projection of the first opening 61 on the substrate 1 may be greater than or equal to 5 μm and less than or equal to 10 μm.

For example, the minimum distance D5 may be 5 μm, 6 μm, 7 μm, 8 μm, 9 μm, or 10 μm. Reasonably setting the minimum distance D5 can reduce impact of the first opening 61 on the first via 51 to improve electrical connection effect between the first electrode 7 and the driver circuit layer 2, and moreover, this can reduce impact of the first opening 61 on the morphology of the isolation structure 4 to enhance overlap effect between the second electrode 9 and the isolation structure 4.

In some possible implementations, as shown in FIGS. 4 and 5, the isolation structure 4 may include a first isolation unit 401 and a second isolation unit 402. A width of an orthographic projection of the first isolation unit 401 on the substrate 1 is greater than a width of an orthographic projection of the second isolation unit 402 on the substrate 1. The orthographic projections of the first opening 61 and the first via 51 on the substrate 1 are both located within the orthographic projection of the first isolation unit 401 on the substrate 1. The orthographic projections of the first opening 61 and the first via 51 on the substrate 1 are both located outside the orthographic projection of the second isolation unit 402 on the substrate 1.

In this embodiment, the first opening 61 is disposed at a position of the first isolation unit 401 with a lager width, which can reduce impact of edges of the first opening 61 on the morphology of the isolation structure 4 to improve flatness of the isolation structure 4, and enhance the overlap effect between the second electrode 9 of the light-emitting unit 10 and the isolation structure 4 to improve the display effect of the display panel.

In some possible implementations, as shown in FIG. 4, a width D6 of an orthographic projection of a side of the first isolation unit 401 facing the substrate 1 on the substrate 1 is greater than a width D7 of an orthographic projection of a side of the second isolation unit 402 facing the substrate 1 on the substrate 1. The orthographic projection of the first opening 61 on the substrate 1 is located within the orthographic projection of a side of the first isolation unit 401 facing the substrate 1 on the substrate 1. In this way, impact of edges of the first opening 61 on the morphology of the isolation structure 4 can be further reduced.

In some embodiments, the width D6 of the orthographic projection of a side of the first isolation unit 401 facing the substrate 1 on the substrate 1 is greater than or equal to 8 μm and less than or equal to 25 μm. For example, the width D6 may be 8 μm, 10 μm, 15 μm, 20 μm, 23 μm, or 25 μm.

In some embodiments, the width D7 of the orthographic projection of a side of the second isolation unit 402 facing the substrate 1 on the substrate 1 is greater than or equal to 4 μm and less than or equal to 10 μm. For example, the width D7 may be 4 μm, 5 μm, 6 μm, 7 μm, 8 μm, 9 μm, or 10 μm.

Reasonably setting the width D6 and width D7 can improve the pixel aperture ratio of the display panel while effectively improving the flatness of the isolation structure 4.

There are several ways to arrange relative positions of the first isolation unit 401 and the second isolation unit 402. For example, as shown in FIG. 4, the first isolation unit 401 and the second isolation unit 402 are arranged around a same isolation opening 11, and the first isolation unit 401 and the second isolation unit 402 are located on different sides of the isolation opening 11, wherein the first isolation unit 401 extends along a second direction, and the second isolation unit 402 extends along a first direction. An extension length of the first isolation unit 401 in the second direction is greater than that of the second isolation unit 402 in the first direction.

In this embodiment, the first isolation unit 401 and the second isolation unit 402 are located on different sides of a same isolation opening 11. For example, the first isolation unit 401 is located on a side of an isolation opening 11 in the first direction and extends along the second direction, while the second isolation unit 402 is located on another side of the isolation opening 11 in the second direction and extends along the first direction.

In some embodiments, the isolation openings 11 may be formed by being surrounded by the first isolation unit 401 and the second isolation unit 402. The width D6 of the orthographic projection of the first isolation unit 401 on the substrate 1 is greater than the width D7 of the orthographic projection of the second isolation unit 402 on the substrate 1. The orthographic projections of the first opening 61 and the first via 51 on the substrate 1 are both located within the orthographic projection of the first isolation unit 401 on the substrate 1, wherein the second direction X intersects with the first direction Y.

In some embodiments, the width D6 of the orthographic projection of the first isolation unit 401 on the substrate 1 is the size of the orthographic projection of the first isolation unit 401 on the substrate 1 along the first direction Y, and the width D7 of the orthographic projection of the second isolation unit 402 on the substrate 1 is the size of the orthographic projection of the second isolation unit 402 on the substrate 1 along the second direction X.

In some embodiments, a gap between adjacent isolation openings 11 arranged along the first direction Y is greater than a gap between adjacent isolation openings 11 arranged along the second direction X. In some embodiments, an interval D6 between adjacent isolation openings 11 arranged along the first direction Y may be greater than an interval D5 between adjacent isolation openings 11 arranged along the second direction X. This can improve the pixel aperture ratio of the display panel and/or enhance the flatness of the isolation structure 4.

In some embodiments, the second direction X is perpendicular to the first direction Y.

The width D6 refers to the size of the orthographic projection of the first isolation unit 401 on the substrate 1 in the first direction Y, and the width D7 refers to the size of the orthographic projection of the second isolation unit 402 on the substrate 1 in the second direction X. The edges of the first opening 61 may affect the flatness of the isolation structure 4, an in turn affect the overlap effect between the second electrode 9 of the light-emitting unit 10 and the isolation structure 4, and accordingly affect the display effect of the display panel.

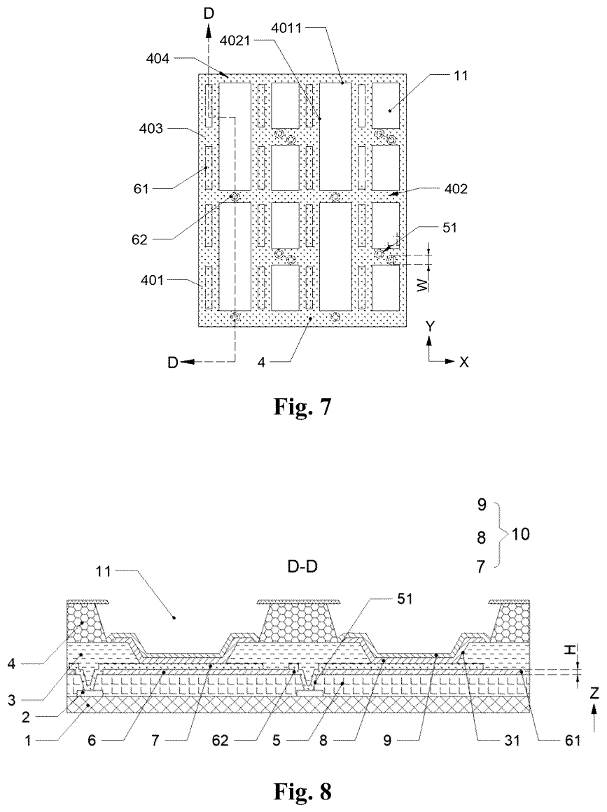

In some other optional embodiments, as shown in FIG. 7, the first isolation unit 401 and the second isolation unit 402 are arranged around different isolation openings 11. Alternatively, as shown in FIG. 13, the orthographic projection of the isolation structure 4 on the substrate 1 is in a mesh-like shape, and the first isolation unit 401 is located at an intersection of the isolation structures 4 extending in different directions. The first isolation unit 401 being located at the intersection allows the first isolation unit 401 to have a wider width and provide better cover on the first opening 61.

In some embodiments, as shown in FIG. 4, an extension length of the first isolation unit 401 in the second direction is greater than an extension length of the second isolation unit 402 in the first direction. The length and width of the first isolation unit 401 may be greater than those of the second isolation unit 402. By the setting that the first opening 61 corresponds to the first isolation unit 401, the size of the first opening 61 can be appropriately increased to improve the vapor discharging effect.

In some embodiments, please refer to FIG. 4 again, an angle β between a line connecting a center of the orthographic projection of the first via 51 on the substrate 1 and a center of the orthographic projection of the first opening 61 on the substrate 1 and the second direction X is greater than or equal to 0 degree and less than 90 degree. For example, the angle β may be 0°, 15°, 30°, 45°, 60°, 70°, 80°, or 85°, etc. In this way, it is possible for the first isolation unit 401 to be narrower, which is more beneficial to increase the opening area of the isolation opening 11.

In some embodiments, the angle β between the line connecting the center of the orthographic projection of the first via 51 on the substrate 1 and the center of the orthographic projection of the first opening 61 on the substrate 1 and the second direction X may be greater than or equal to 0 degree and less than or equal to 30 degrees. For example, the angle β may be 0, 5°, 10°, 15°, 20°, 25°, or 30°, etc. In this way, it is possible for the first isolation unit 401 to be narrower, which is more beneficial to increase the opening area of the isolation opening 11.

In some embodiments, please refer to FIG. 1, the angle β between the line connecting the center of the orthographic projection of the first via 51 on the substrate 1 and the center of the orthographic projection of the first opening 61 on the substrate 1 and the second direction X may be equal to 0 degree. That is, an arrangement direction of the first via 51 and the first opening 61 is the same as the extension direction of the first isolation unit 401, which can provide more space for reducing the width of the first isolation unit 401, thereby further increase the opening area of the isolation opening 11.

In some possible implementations, please refer to FIGS. 1 and 2, for a light-emitting unit 10, the first via 51 corresponding to the first electrode 7 of the light-emitting unit 10 and at least one first opening 61 adjacent the light-emitting unit 10 are located on a same side of the light-emitting unit 10.

In some embodiments, the first via 51 electrically connected or corresponding to the first electrode 7 of the light-emitting unit 10 is located on one of opposite sides of the light-emitting unit 10 along the first direction Y; and the first opening 61 adjacent to the light-emitting unit 10 is located on at least one of the opposite sides of the light-emitting unit 10 along the first direction Y.

For example, the first vias 51 electrically connected or corresponding to respective first electrodes 7 of multiple light-emitting units 10 arranged along the second direction X are located on the same side of respective opposite sides of the light-emitting units 10 along the first direction Y.

For example, there may be a plurality of first openings 61. For example, the plurality of first openings 61 may be disposed at intervals.

For example, as shown in FIGS. 1 and 4, the plurality of first openings 61 may be arranged along the second direction X. For example, the plurality of first openings 61 may be arranged at equal or unequal intervals along the second direction X. For example, a distance between adjacent first openings 61 arranged along the second direction X may be greater than or equal to a distance between centers of adjacent isolation openings 11 arranged along the second direction X, and/or the distance between adjacent first openings 61 arranged along the second direction X may be less than twice the distance between the centers of adjacent isolation openings 11 arranged along the second direction X.

For example, the plurality of first openings 61 are arranged along the first direction Y. For example, the plurality of first openings 61 may be arranged at equal or unequal intervals along the first direction Y. For example, the distance between adjacent first openings 61 arranged along the first direction Y may be greater than or equal to the distance between the centers of adjacent isolation openings 11 arranged along the first direction Y, and/or the distance between adjacent first openings 61 arranged along the first direction Y may be less than twice the distance between the centers of adjacent isolation openings 11 arranged along the first direction Y.

In some embodiments, as shown in FIGS. 1 and 4, the isolation openings 11 and the first vias 51 are alternately arranged along the first direction Y.

In this way, setting the first via 51 corresponding to multiple light-emitting units 10 arranged along the first direction Y on the same side and setting the first openings 61 corresponding to the multiple light-emitting units 10 arranged along the first direction Y on the same side can make arrangement of the plurality of first vias 51 and the plurality of first openings 61 in the display panel more uniform.

In some embodiments, at least one of the first openings 61 and at least one of the first vias 51 may be arranged along the second direction X, with the first direction Y intersecting with the second direction X.

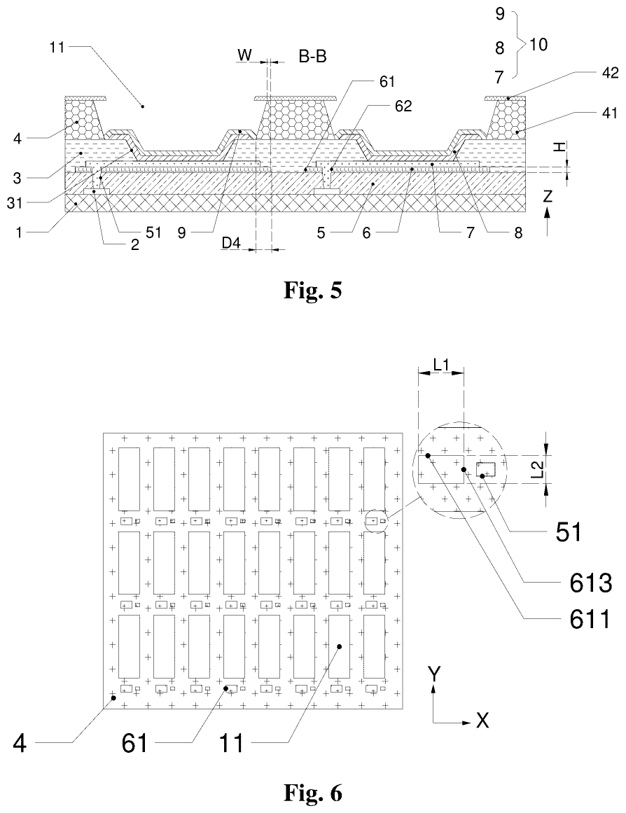

In some embodiments, as shown in FIG. 6, the plurality of first openings 61 and the plurality of first vias 51 are alternately arranged along the second direction X.

With a part of the isolation structure 4 extending along the second direction X and at least one of the first openings 61 and at least one of the first vias 51 being arranged along the second direction X can reduce a space occupied by the first opening 61 and the first via 51, thereby increasing an opening area of a corresponding isolation opening 11 and improving the pixel aperture ratio of the display panel.

In some embodiments, the orthographic projections of the first opening 61 and the first via 51 on the substrate 1 may be both located within an orthographic projection of a region between adjacent isolation openings 11 arranged along the first direction Y.

In some embodiments, the orthographic projections of the first opening 61 and the first via 51 on the substrate 1 may be both located outside the orthographic projection of the region between adjacent isolation openings 11 arranged along the second direction X.

A width of a part of the isolation structure 4 extending along the second direction X is greater than a width of a part of the isolation structure 4 extending along the first direction Y. Setting the first opening 61 and the first via 51 on the side of the isolation structure 4 extending along the second direction X near the substrate 1 can reduce impact of the first opening 61 on the morphology of the isolation structure 4.

For example, a gap between adjacent isolation openings 11 arranged along the first direction Y may be greater than a gap between adjacent isolation openings 11 arranged along the second direction X. For example, an interval between adjacent isolation openings 11 arranged along the first direction Y may be greater than an interval between adjacent isolation openings 11 arranged along the second direction X. Setting the orthographic projections of the first opening 61 and the first via 51 on the substrate 1 in the gap between adjacent isolation openings 11 which have a larger gap can improve the pixel aperture ratio of the display panel.

For example, the orthographic projections of the first opening 61 and the first via 51 on the substrate 1 may be both located within the orthographic projection of a region between adjacent pixel openings 31 arranged along the first direction Y. For example, the orthographic projection of the first opening 61 and the first via 51 on the substrate 1 may be located outside the orthographic projection of area region between adjacent pixel openings 31 arranged along the second direction X.

For example, a gap between adjacent pixel openings 31 arranged along the first direction Y may be greater than a gap between adjacent pixel openings 31 arranged along the second direction X. For example, an interval between adjacent pixel openings 31 arranged along the first direction Y may be greater than an interval between adjacent pixel openings 31 arranged along the second direction X. Setting the orthographic projection of the first opening 61 and the first via 51 on the substrate 1 in the gap between adjacent pixel openings 31 which have a larger gap can improve the pixel aperture ratio of the display panel.

In some possible implementations, as shown in FIGS. 4, 5, and 7, the isolation structure 4 may include a third isolation unit 403 and a fourth isolation unit 404. A length of an orthographic projection of the third isolation unit 403 on the substrate 1 is greater than a length of an orthographic projection of the fourth isolation unit 404 on the substrate 1. The orthographic projection of the first opening 61 on the substrate 1 is located within the orthographic projection of the third isolation unit 403 on the substrate 1, and the orthographic projection of the first opening 61 on the substrate 1 is located outside the orthographic projection of the fourth isolation unit 404 on the substrate 1.

In these optional embodiments, the first opening 61 is correspondingly set below the third isolation unit 403 which have a longer length. By reasonably setting the length of the first opening 61, a distribution area of the first opening 61 can be increased.

In some embodiments, as shown in FIG. 4, the third isolation unit 403 and the first isolation unit 401 can be reused, and the fourth isolation unit 404 and the second isolation unit 402 can be reused. That is, a width of the third isolation unit 403 may be greater than that of the fourth isolation unit 404, so that the first opening 61 can be correspondingly set below the third isolation unit 403, which has a relatively large length and width.

In some other optional embodiments, the width of the third isolation unit 403 may be smaller than the width of the fourth isolation unit 404.

In some embodiments, there are several ways to arrange the relative positions of the third isolation unit 403 and the fourth isolation unit 404. For example, as shown in FIGS. 7 and 8, the third isolation unit 403 and the fourth isolation unit 404 may be arranged around the same pixel opening 31, and are located on different sides of the pixel opening 31. In some other optional embodiments, the third isolation unit 403 and the fourth isolation unit 404 may be arranged around different pixel openings 31. Alternatively, an orthographic projection of the isolation structure 4 on the substrate 1 may be in a mesh-like shape, and the third isolation unit 403 may be located at an intersection of the isolation structure 4 extending in different directions. The third isolation unit 403 being located at the intersection allow the third isolation unit 403 to have a wider width and provide better cover on the first opening 61.

In some possible implementations, please refer to FIGS. 4 and 7 again, the orthographic projection of isolation opening 11 on the substrate 1 includes a fifth edge 4011 and a sixth edge 4021. The fifth edge 4011 extends along the second direction X, and the sixth edge 4021 extends along the first direction Y.

For example, each isolation opening 11 includes two fifth edges 4011 arranged opposite each other along the first direction Y. For example, each isolation opening 11 includes two sixth edges 4021 arranged opposite each other along the second direction X. In some embodiments, the orthographic projection of the first isolation unit 401 on the substrate 1 is located between the fifth edges 4011 of adjacent isolation openings 11, and the orthographic projection of the second isolation unit 402 on the substrate 1 is located between the sixth edges 4021 of adjacent isolation openings 11. The extension length of the fifth edge 4011 is smaller than that of the sixth edge 4021.

In some embodiments, as shown in FIG. 4, the first opening 61 is located between the two fifth edges 4011 of adjacent isolation openings 11. That is, the first opening 61 is set at the shorter edge of the isolation opening 11, and the first opening 61 is not set at the longer edge of the isolation opening 11. The width of a part of the isolation structure 4 without the first opening 61 is relatively narrower than that of a part of the isolation structure 4 with the first opening 61, which is more beneficial to reduce the width of the part of the isolation structure 4 at the longer edge of the isolation opening 11, thereby improving the opening area of the isolation opening 11 and improving the pixel aperture ratio of the display panel, and accordingly improve the display effect of the display panel.

In some embodiments, as shown in FIG. 7, the orthographic projection of the third isolation unit 403 on the substrate 1 is located between the sixth edges 4021 of adjacent isolation openings 11, and the orthographic projection of the fourth isolation unit 404 on the substrate 1 is located between the fifth edges 4011 of adjacent isolation openings 11. The extension length of the fifth edge 4011 is smaller than that of the sixth edge 4021. The first opening 61 is located between the two sixth edges 4021 of adjacent isolation openings 11. In some embodiments, the orthographic projection of the first opening 61 on the substrate 1 extends along the second direction to maximize the distribution area of the first opening 61 and improve the vapor discharging effect.

In some embodiments, as shown in FIG. 7, the inorganic layer 6 may be further provided with a plurality of second via 62 penetrating the inorganic layer 6 along the thickness direction of the substrate 1. The orthographic projection of the second via 62 on the substrate 1 is located within the orthographic projection of the fourth isolation unit 404 on the substrate 1, and the orthographic projection of the second via 62 on the substrate 1 overlaps with the orthographic projection of the first via 51 on the substrate 1. In these optional embodiments, the second via 62 and the first via 51 are disposed corresponding to the fourth isolation unit 404 in order for the first electrode 7 being connected to the driver circuit layer 2, and the first opening 61 is disposed corresponding to the third isolation unit 403 in order for vapor discharging.

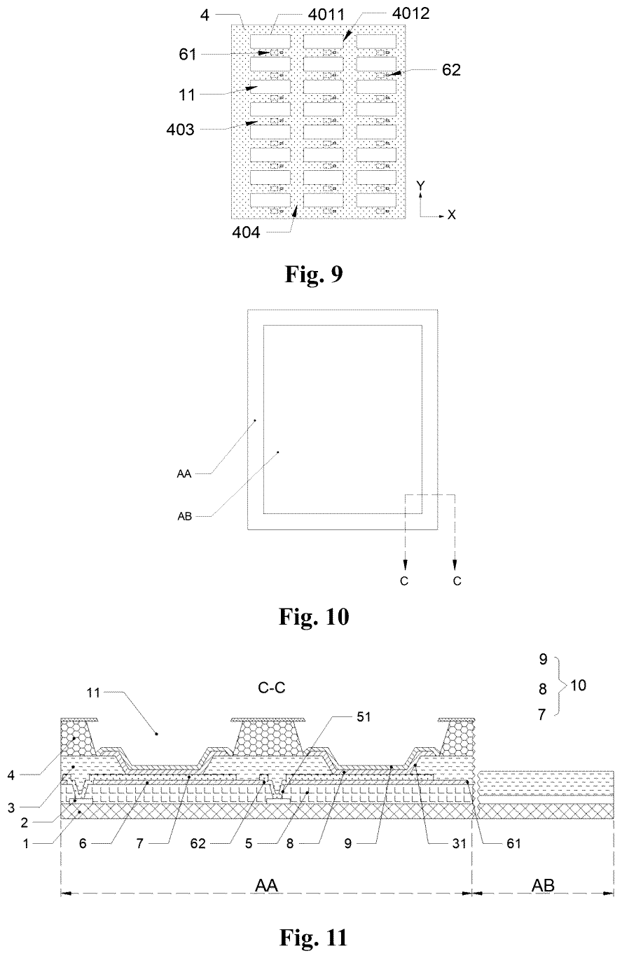

Alternatively, in some other optional embodiments, as shown in FIG. 9, the extension length of the fifth edge 4011 may be greater than the extension length of the sixth edge 4021. The orthographic projection of the third isolation unit 403 on the substrate 1 is located between the fifth edges 4011 of adjacent isolation openings 11, and the orthographic projection of the fourth isolation unit 404 on the substrate 1 is located between the sixth edges 4021 of adjacent isolation openings 11. That is, the first opening 21 may be disposed between the longer fifth edges 4011 of adjacent isolation openings 11. The two fifth edges 4011 of adjacent isolation openings 11 are arranged opposite and adjacent to each other. Due to the extension length of the fifth edge 4011 being greater than that of the sixth edge 4021, there is more space for disposing between the two fifth edges 4011 of adjacent isolation openings 11. Therefore, a first opening 61 of a more suitable size can be disposed between the two fifth edges 4011 of adjacent isolation openings 11. As a result, since a more suitable size of the first opening is disposed, the inorganic layer 6 can effectively block external water vapor from entering the insulating layer 5 before forming of the first electrode 7 of the light-emitting unit 10. After the first electrode 7 of the light-emitting unit 10 is formed and during baking, the water vapor in insulation layer 5 can be more timely discharged from the first opening 61, which makes it is less likely to cause the insulation layer 5 and the inorganic layer 6 to crack and cause dark spots appearing in the corresponding light-emitting units 10, thereby improving reliability and the display effect of the display panel.

Based on the above design, by disposing the first opening 61 in the inorganic layer 6 between the two fifth edges 4011 of adjacent isolation openings 11, this embodiment can enable the water vapor in the insulation layer 5 to be discharged more timely through the first opening 61, which makes it is less likely to cause the insulation layer 5 and the inorganic layer 6 to crack and cause dark spots appearing in corresponding light-emitting units 10, thereby improving the reliability and the display effect of the display panel.

In some possible implementations, as shown in FIG. 4, the orthographic projections of the first opening 61 and the first via 51 on the substrate 1 may be both located within the orthographic projection of the side of the isolation structure 4 facing the substrate 1 on the substrate 1, so that the first opening 61 and the first via 51 are offset from the isolation opening 11 and the pixel opening 31, so as to maximize the distribution area of the pixel opening 31 and pixel aperture ratio.

In some embodiments, a minimum one of distances between edges of the orthographic projection of the side of the first opening 61 away from the substrate 1 on the substrate 1 and an orthographic projection of a sidewall of the isolation structure 4 facing the isolation opening 11 on a side of the sidewall close to the substrate 1 on the substrate 1 may be greater than 0 and less than or equal to 10 μm.

In some possible implementations, please refer to FIGS. 10 to 12. The display panel may include a display area AA and a non-display area AB, for example, the non-display area AB surrounds at least a portion of the display area AA. The display panel may further include the pixel defining layer 3 mentioned above, which extends from the display area AA to the non-display area AB.

In related arts, the pixel defining layer 3 located in the non-display area AB is provided with a plurality of third openings 72 penetrating through the pixel defining layer 3. Before forming of the light-emitting units 10, external water vapor can easily enter the non-display area AB through the third openings 72, then enter the display area AA from the non-display area AB, and finally enter the light-emitting units 10, causing dark spots appearing in corresponding light-emitting units 10. The pixel defining layer 3 may include an inorganic insulating material.

The application adopts the following two methods to solve the above-mentioned problem in related arts.

In some embodiments, please refer to FIG. 11 again, the orthographic projection of the isolation structure 1 on the substrate 1 is located within an orthographic projection of the pixel defining layer 3 on the substrate 1. The pixel defining layer 3 extends from the display area AA to the non-display area AB. The pixel defining layer 3 located in the non-display area AB isolates the isolation structure 8 from the substrate 1. The pixel defining layer 3 defines a plurality of pixel openings 31 in the display area AA, and the pixel openings 31 communicate with the isolation openings 44; at least a portion of the light-emitting units 10 are located at the pixel openings 31, and the orthographic projection of the first opening 61 on the substrate 1 is offset from an orthographic projection of the pixel opening 31 on the substrate 1.

After long-term researches, the inventors found that absence of the third openings 72 in the pixel defining layer 3 located in the non-display area AB does not affect performance of the display panel. Therefore, in this embodiment, there is no the third openings 72 in the pixel defining layer 3 located in the non-display area AB, the pixel defining layer 3 located in the non-display area AB can also isolate external water vapor, and it is less likely that the external water vapor can pass through the pixel defining layer 3 located in the non-display area AB to enter the light-emitting units 10 before forming of the light-emitting units 10.

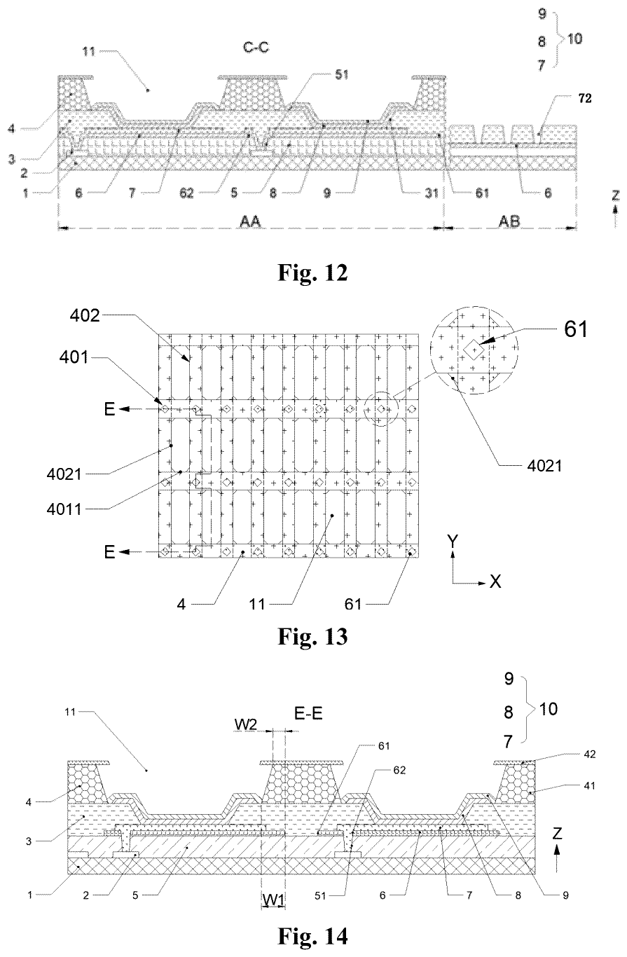

In some other embodiments, please refer to FIG. 12 again, the pixel defining layer 3 located in the non-display area AB may be provided with the third openings 72 penetrating through the pixel defining layer 3 along the thickness direction Z of substrate 1, the inorganic layer 6 extends from the display area AA to the non-display area AB, and the orthographic projection of the inorganic layer 6 on the substrate 1 covers orthographic projections of the third openings 72 on the substrate 1.

In this embodiment, there retains the third opening 72 in the pixel defining layer 3, and the inorganic layer 6 extends from the display area AA to the non-display area AB. In this way, the inorganic layer 6 can seal the third openings 72, making it difficult for external water vapor to enter the light-emitting units 10 through the third openings 72.

In some embodiments, as shown in FIGS. 1 to 12, the orthographic projection of the first opening 61 on the substrate 1 may be in a shape of polygon (e.g. rectangular, or square) or ellipse or circle. Thus, the shape of the first opening 61 can be reasonably set according to actual needs.

In some possible implementations, please refer to FIGS. 7 and 8 again, the inorganic layer 6 may be further provided with a plurality of second vias 62 penetrating through the inorganic layer 6 along the thickness direction Z of substrate 1.

For example, the second via 62 may be located between the two sixth edges 4021 of adjacent isolation openings 11, and an orthographic projection of the second via 62 on the substrate 1 overlaps with the orthographic projection of the first via 51 on the substrate 1.

In some embodiments, the first electrode 7 may be electrically connected to the driver circuit layer 2 through the second via 62 and the first via 51, and the orthographic projection of the second via 62 on the substrate 1 may overlap with the orthographic projection of the first via 51 on the substrate 1.

By providing the second via 62 between the two sixth edges 4021 of adjacent isolation openings 11, the water vapor in the insulation layer 5 more timely discharged from a combination of the first opening 61 and the second via 62 in the inorganic layer 6.

In some possible implementations, please refer to FIGS. 7 and 8 again, a center of an orthographic projection of the second via 62 on the substrate 1 coincides with a center of the orthographic projection of the first via 51 on the substrate 1. In this way, it makes easier that the first electrode 7 can be electrically connected to the driver circuit layer 2 through the second via 62 and the first via 51.

In some embodiments, please refer to FIGS. 13 and 14 again, a minimum one W1 of distances between edges of an orthographic projection of a side of the first opening 61 away from substrate 1 on the substrate 1 and an orthographic projection of a sidewall of the isolation structure 4 facing the isolation opening 11 on a side of the sidewall close to substrate 1 on the substrate is greater than 0 μm and less than or equal to 10 μm. For example, the distance W1 may be 0.5 μm, 1 μm, 2 μm, 3 μm, 4 μm, 5 μm, 6 μm, 7 μm, 8 μm, 9 μm, or 10 μm.

In some embodiments, the minimum one W1 of distances between edges of the orthographic projection of the side of the first opening 61 away from the substrate 1 on the substrate 1 and the orthographic projection of the sidewall of the isolation structure 4 facing the isolation opening 11 on the side closer to the substrate 1 on the substrate may be greater than or equal to 1 μm and less than or equal to 10 μm. For example, the distance W1 may be 1 μm, 2 μm, 3 μm, 4 μm, 5 μm, 6 μm, 7 μm, 8 μm, 9 μm, or 10 μm.

Reasonably setting the distance W1 can reduce impact of edges of the first opening 61 on the morphology of the isolation structure 4, and effectively improve the flatness of the isolation structure 4.

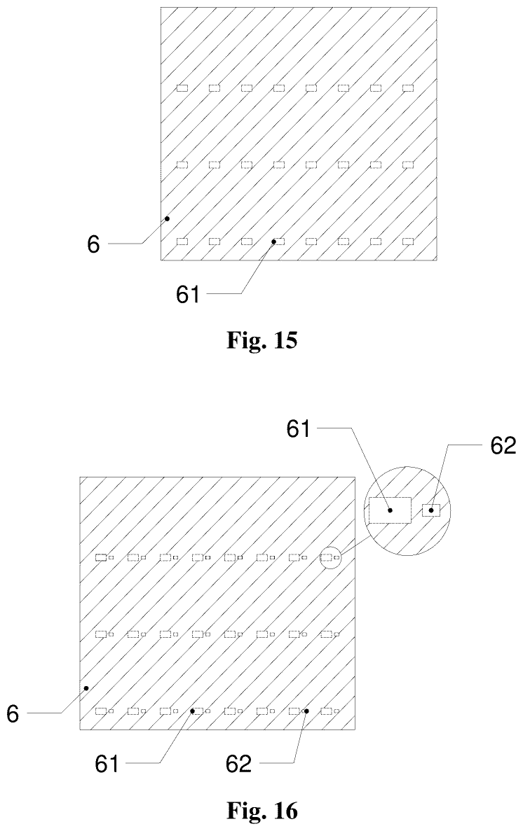

In some possible implementations, as shown in FIGS. 15 and 16, the orthographic projection of the inorganic layer 6 on the substrate 1 is in a mesh-like shape, and the plurality of first openings 61 are spaced apart from each other. The inorganic layer 6 covers the entire insulation layer 5, which can further improve the effect of blocking against the water vapor in the insulation layer 5. For example, the inorganic layer 6 may be in contact with the first electrode 7. For example, the orthographic projection of the pixel opening 31 on the substrate 1 may be located within the orthographic projection of the inorganic layer 6 on the substrate 1.

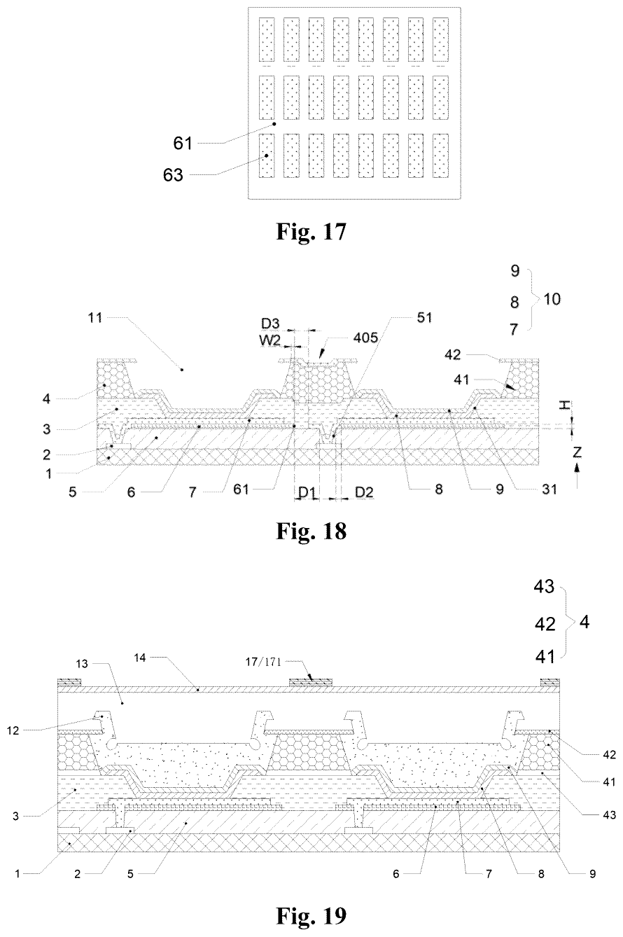

In some other optional embodiments, as shown in FIG. 17, the plurality of first openings 61 communicate with each other to separate the inorganic layer 6 into a plurality of body parts 63 spaced apart from each other. In these optional embodiments, the plurality of first openings 61 communicate with each other, resulting in the first openings 61 occupying a larger distribution area and in turn improved vapor discharging effect.

In some possible implementations, as shown in FIG. 10, the display panel may include a display area, the plurality of first openings 61 are located in the display area, and a ratio of a sum of areas of the orthographic projections of the plurality of first openings 61 on the substrate 1 to an area of the display area is 5% to 20%. For example, the ratio of the sum of areas of the orthographic projections of the plurality of first openings 61 on the substrate 1 to the area of the display area may be 5%, 12%, 18%, 21.5%, 20%, etc., so as to avoid from resulting a too small distribution area of the plurality of first openings 61 to achieve the vapor discharging effect, and also avoid from resulting a too large distribution area of the plurality of first openings 61 to achieve protective effect of the inorganic layer 6.

In some possible implementations, as shown in FIG. 18, there is a recessed part 405 formed on a surface of the isolation structure 4 away from the substrate 1 and recessed towards the substrate 1. An orthographic projection of the recessed part 405 on the substrate 1 overlaps at least partially with the orthographic projection of the first opening 61 on the substrate 1. In these optional embodiments, the isolation structure 4 is located on the inorganic layer 6. Due to presence of the first openings 61, a surface of a film layer where the isolation structure 4 is located is not flat, so it is easy to form the recessed part 405 on the isolation structure 4. The recessed part is located above the first opening 61.

In some possible implementations, as shown in FIG. 18, the isolation structure 4 may include a first isolation part 41 and a second isolation part 42 stacked in a direction away from the substrate 1. The second isolation part 42 protrudes towards the isolation opening 11 relative to the first isolation part 41, and the orthographic projection of the first opening 61 on the substrate 1 is located within an orthographic projection of the first isolation part 41 on the substrate 1.

In these optional embodiments, the isolation structure 4 includes the first isolation part 41 and a second isolation part 42. A cross-sectional dimension of the second isolation part 42 is larger than that of the first isolation part 41, such that the second isolation part 42 can protrude towards the isolation opening 11 relative to the first isolation part 41, and thus a concave shape is formed under the second isolation part 42 to facilitate the isolation structure 4 to separate a light-emitting material into independent light-emitting units 10. The orthographic projection of the first opening 61 on the substrate 1 is located within the orthographic projection of the first isolation part 41 on the substrate 1, i.e., the first opening 61 is under the first isolation part 41 which has a smaller size, so that the isolation structure 4 can better cover the first opening 61 and further improve the pixel aperture ratio.

In some optional embodiments, as shown in FIG. 18, the first isolation part 41 may include a first surface facing the substrate 1 and a second surface facing away from the substrate 1. A minimum one W2 of distances between edges of a smaller one of orthographic projections of the first surface and the second surface on the substrate 1 and edges of the orthographic projection of the first opening 61 on the substrate 1 is greater than or equal to 1 μm. For example, a cross-section of the first isolation part 41 gradually decreases in a direction away from the substrate 1, and the second surface of the first isolation part 41 facing away from the substrate 1 has the smallest cross-sectional area, then the minimum one of distances between edges of the second surface of the first isolation part 41 on the substrate 1 and edges of the orthographic projection of the first opening 61 on the substrate 1 is greater than or equal to 1 μm.

In these optional embodiments, the minimum one of distances between edges of the orthographic projection of the first opening 61 on the substrate 1 and edges of the orthographic projection of the first isolation part 41 on the substrate 1 is relatively large to avoid that the first isolation portion 41 cannot cover the first opening 61 due to process errors.

In some optional embodiments, as shown in FIG. 19, the display panel may further include a plurality of signal traces 17, and an orthographic projection of the signal trace 17 on the substrate 1 overlaps at least partially with the orthographic projection of the first opening 61 on the substrate 1. The signal traces may include a plurality of touch trace 171 of the display panel, and/or the driver circuit layer 2 may include a plurality of array traces, and the signal traces 17 may include the array traces, which can reduce a local thickness of the display panel.

In some embodiments, as shown in FIG. 19, the touch traces 171 may be located on a side of a third encapsulation layer 14 away from the second encapsulation layer 13 to reduce impact of the touch traces 171 on encapsulation effect. In some embodiments, the touch traces 171 may be in a mesh-like shape and used to form touch electrodes. In some embodiments, an orthographic projection of the touch trace 171 on the substrate 1 may be located within the orthographic projection of the isolation structure 4 on the substrate 1, that is, the touch traces 171 may be offset from the isolation openings 11, thereby reducing impact of the touch traces 171 on light output effect.

In some embodiments, the array trace may include at least one of a data signal line, a scanning signal line, a power supply voltage signal line, a reference voltage signal line, and a lighting control signal line.

In some embodiments, an extension direction of the signal trace 17 may intersect with an extension direction of the first opening 61. The extension direction of signal trace 17 is a length direction of signal trace 17, and the signal trace 17 has a larger size in its extension direction than in its other directions. The extension direction of the first opening 61 is an extension direction of the orthographic projection of the first opening 61 on the substrate 1, and the size of the orthographic projection of the first opening 61 on the substrate 1 in its extension direction is greater than that in its other directions. For example, the extension direction of signal trace 17 may be the first direction Y and the extension direction of the first opening 61 may be the second direction X, so as to minimize an overlap area between the signal trace 17 and the first opening 61 as much as possible, and reduce impact of the first opening 61 on the signal trace 17. In some embodiments, in the case where the signal traces 17 includes the plurality of touch traces 171, for a signal trace 17 and a first opening 61 which have their orthographic projections overlapped with each other, the extension direction of the touch trace 171 intersects with the extension direction of the first opening 61. That is, when the orthographic projection of the touch trace 171 on the substrate 1 overlaps at least partially with the orthographic projection of the first opening 61 on the substrate 1, the extension direction of the touch trace 171 intersects with the extension direction of the first opening 61.

In some embodiments, in the case where the signal traces 17 includes the plurality of array wirings, for an array trace and a first opening 61 which have their orthographic projections overlapped with each other, the extension direction of the array trace intersects with the extension direction of the first opening 61. That is, when an orthographic projection of the array trace on the substrate 1 overlaps at least partially with the orthographic projection of the first opening 61 on the substrate 1, the extension direction of the array trace intersects with the extension direction of the first opening 61.

In some embodiments, a line width of the signal trace 17 may be smaller than a width of the first opening 61. A width direction of the signal trace 17 is perpendicular to the extension direction of the signal trace 17, and both the width direction and extension direction of the signal trace 17 are parallel to a display surface of the display panel. Similarly, a width direction of the first opening 61 is perpendicular to the extension direction of the first opening 61, and both the width direction and extension direction of the first opening 61 are parallel to the display surface of the display panel. For example, in the case where the extension direction of signal trace 17 is the first direction Y and the width direction of signal trace 17 is the second direction X, the line width of the signal trace 17 is the size of the signal trace 17 in the second direction X. In the case of the extension direction of the first opening 61 is the second direction X and the width direction of the first opening 61 is the first direction Y, the width of the first opening 61 is an extension size of the first opening 61 in the first direction Y. In this embodiment, the first opening 61 has a relatively larger width, which results in a larger distribution area of the first opening 61, thereby improving the vapor discharging effect.

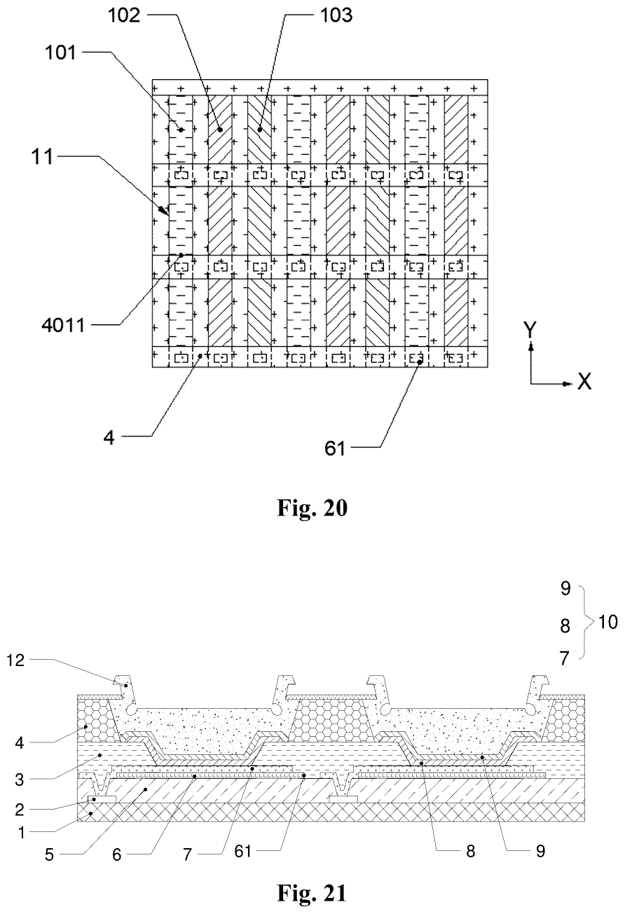

In some embodiments, in the case where the signal traces 17 includes the plurality of touch traces 171, the line width of the touch trace 171 is smaller than the width of the first opening 61. In some embodiments, in the case where the signal traces 17 includes the plurality of array traces, a line width of the array trace is smaller than the width of the first opening 61. In some embodiments, please refer to FIG. 20, the light-emitting units 10 may include a plurality of first light-emitting units 101 and a plurality of second light-emitting units 102 which are used for emitting different colors. The first light-emitting units 101 and the second light-emitting units 102 are alternately arranged along the second direction X; the fifth edges 4011 of the isolation openings 11 respectively corresponding to the first light-emitting units 101 and the second light-emitting units 102 arranged along the second direction X are at least partially collinear.

In some embodiments, the light-emitting units 10 may include a plurality of first light-emitting unit 101, a plurality of second light-emitting units 102, and a plurality of third light-emitting units 103 which are used for emitting different colors. The first light-emitting units 101, the second light-emitting units 102, and the third light-emitting units 103 are arranged in the order along the second direction X in a cyclic manner; the fifth edges 4011 of the isolation openings 11 respectively corresponding to the first light-emitting units 101, the second light-emitting units 102, and the third light-emitting units 103 arranged along the second direction X are at least partially collinear.

In some embodiments, the sixth edges 4021 of the isolation openings 11 corresponding to the first light-emitting units 101 arranged along the first direction Y are at least partially collinear.

In some embodiments, the sixth edges 4021 of the isolation openings 11 corresponding to the second light-emitting units 102 arranged along the first direction Y are at least partially collinear.

In some embodiments, the sixth edges 4021 of the isolation openings 11 corresponding to the third light-emitting units 103 arranged along the first direction Y are at least partially collinear.

For example, the first light-emitting units 101 may be used for emitting one of red, green, and blue colors. For example, the second light-emitting unit s102 may be used for emitting another one of the red, green, and blue colors. For example, the third light-emitting units 103 may be used for emitting a remaining one of the red, green, and blue colors.

In this way, the first light-emitting units 101, the second light-emitting units 102, and the third light-emitting units 103 are arranged in more uniform way, thereby improving the display effect of the display panel.

In some embodiments, the size of the first opening 61 along the second direction X is greater than the size of the first opening 61 along the first direction Y.

In some embodiments, the orthographic projection of the first opening 61 on the substrate 1 may be in an orthogonal shape, such as a rectangle.

In this way, while ensuring that the edges of the first opening 61 does not affect the morphology of the isolation structure 4, the width of the first isolation unit 401 can be set narrower, thereby further increasing the opening area of the isolation opening 11 and further improving the pixel aperture ratio of the display panel.

In some embodiments, the shape of the orthographic projection of the first opening 61 on the substrate 1 may include one or more of a circle, an ellipse, a polygon (such as a quadrilateral, a pentagon, a hexagon, an octagon, etc.), a rounded polygon (such as a rounded rectangle), and the like.

In some possible implementations, please refer to FIGS. 3-6 again, the orthographic projection of the first opening 61 on the substrate 1 may include a first edge 611 and a seventh edge 613. The first edge 611 extends along the second direction X, and the seventh edge 613 extends along the first direction Y.

For example, an extension length L2 of the seventh edge 613 is smaller than an extension length L1 of the first edge 611.

In some embodiments, a ratio of the extension length L1 of the first edge 611 to the extension length L2 of the seventh edge 613 is greater than 1 and less than or equal to 12.5. For example, the ratio of the length L1 to the length L2 may be 1, 2, 3, 5, 7, 9, 10, 11, 12, or 12.5. Reasonably setting the ratio of the length L1 to the length L2 allows the first opening 61 to extend longer in the second direction X while effectively improve the flatness of isolation structure 4, thereby increasing the pixel aperture ratio of the display panel.

In some embodiments, the extension length L1 of the first edge 611 may be greater than or equal to 5 μm and less than or equal to 25 μm. For example, the length L1 may be 5 μm, 7 μm, 10 μm, 15 μm, 20 μm, 23 μm, or 25 μm, etc.

In some embodiments, the extension length L2 of the seventh edge 613 may be greater than or equal to 2 μm and less than or equal to 10 μm. For example, the length L2 may be 2 μm, 3 μm, 5 μm, 7 μm, 9 μm, or 10 μm.

In some possible implementations, the inorganic layer 6 may include a water-resistant material, and/or the insulating layer 5 may include an organic material.

It is easy for water vapor to transfer in an organic material, so the water vapor can easily transfer in the insulation layer 5. The water-resistant material can block the water vapor, so the inorganic layer 6 can block the water vapor in the insulation layer 5 from entering the light-emitting units 10.

In some embodiments, the inorganic layer 6 may include an inorganic material.

Specifically, the inorganic layer 6 may include a material of at least one of silicon nitride, silicon oxide, or silicon oxynitride. Reasonably setting the material of the inorganic layer 6 can improve an effect of the inorganic layer 6 in blocking the water vapor in the insulation layer 5.

In some possible implementations, please refer to FIGS. 15 and 16, the orthographic projection of the inorganic layer 6 on the substrate 1 may be in a mesh-like shape. The inorganic layer 6 covers an entire surface of the insulation layer 5, which can further enhance the effect in blocking the water vapor in the insulation layer 5. For example, the first opening 61 may be included in a hole of the mesh-like shape.

In some embodiments, a side of the insulation layer 5 away from the substrate 1 may be in contact with a side of the inorganic layer 6 close to the substrate 1. In this way, the inorganic layer 6 can more directly block the water vapor in the insulation layer 5, thereby further improving the effect of block against the water vapor in the insulation layer 5.

In some embodiments, please refer to FIG. 2 again, a thickness H of the inorganic layer 6 along the thickness direction Z of substrate 1 may be greater than or equal to 500 Å and less than or equal to 5000 Å. For example, the thickness H may be set to 500 Å, 1000 Å, 1500 Å, 2000 Å, 3000 Å, 4000 Å, 4500 Å, or 5000 Å. Reasonably setting the thickness H can improve the effect of the inorganic layer 6 in blocking the water vapor in insulation layer 5.

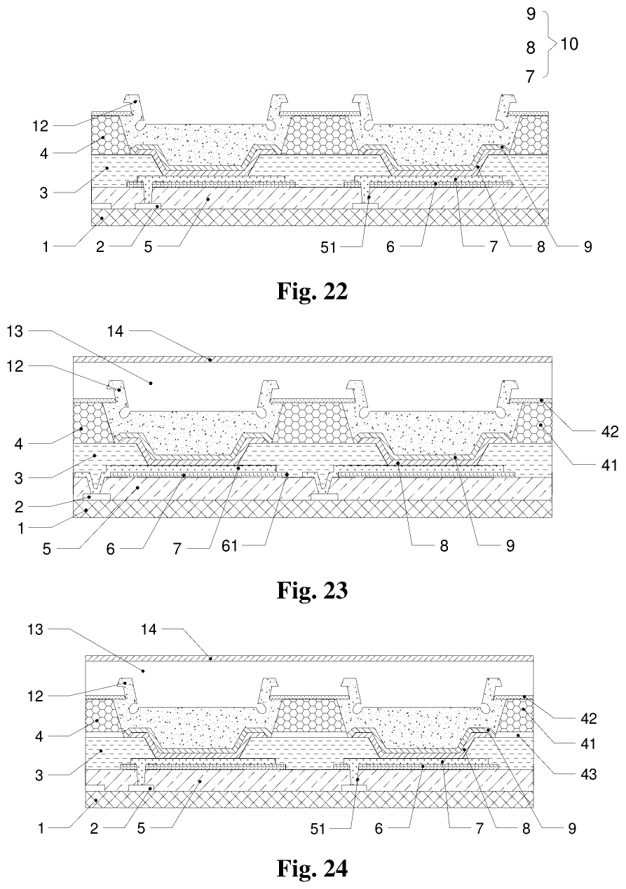

In some possible implementations, please refer to FIGS. 21 and 22, the display panel may further include an encapsulation unit 12 located on a side of the light-emitting unit 10 away from the substrate 1. For example, there may be a plurality of encapsulation units 12. For example, at least some of the encapsulation units 12 extend from the side of the isolation structure 4 facing the isolation opening 11 to the side of the isolation structure 4 away from the substrate 1, and the encapsulation units 12 are spaced apart on the side of the isolation structure 4 away from the substrate 1.

For example, the display panel includes a plurality of encapsulation units 12 which are spaced at intervals. For example, the light-emitting units 10 that emit light of different colors correspond to different encapsulation units 12.

In some embodiments, there is a gap between the encapsulation unit 12 located on the side of the isolation structure 4 away from the substrate 1 and the side of the isolation structure 4 away from the substrate 1.

During patterning of the light-emitting units 10, a first encapsulation material layer is separated by the isolation structure 4 to form the encapsulation units 12. Each of the encapsulation unit 12 can independently and completely encapsulate an entire corresponding light-emitting unit 10, thereby improving the display effect of the display panel.

In some possible implementations, please refer to FIG. 19, the display panel may further include a second encapsulation layer 13 located on the side of the encapsulation units 12 away from the substrate 1.

For example, the display panel may further includes a third encapsulation layer 14 located on the side of the second encapsulation layer 13 away from the substrate 1.

In some embodiments, the encapsulation units 12 may include an inorganic material, and/or the third encapsulation layer 14 may include an inorganic material, and the second encapsulation layer 13 may include an organic material.

For example, the encapsulation units 12 and the third encapsulation layer 14 may be formed by chemical vapor deposition (CVD), and the second encapsulation layer 13 may be formed by ink-jet printing (IJP). The second encapsulation layer 13 and the third encapsulation layer 14 can achieve better encapsulation of the light-emitting units 10, thereby further improving encapsulation quality of the display panel.

For example, the isolation structure 4 may include a conductive material, and the second electrodes 9 are electrically connected to the isolation structure 4.

In some possible implementations, please refer to FIG. 4 again, the isolation structure 4 may include a first isolation part 41 and a second isolation part 42 which are stacked in the order along the direction away from the substrate 1. An orthographic projection of side of the first isolation part 41 away from the substrate 1 is located within an orthographic projection of the second isolation part 42 on the substrate 1.

Since the second isolation part 42 is located on the side of the first isolation part 41 away from the substrate 1, and in a plane parallel to the substrate 1, a lateral width of the second isolation part 42 is greater than that of the first isolation part 41, the second isolation part 42 will make the light-emitting material layer and the material layer for the second electrodes 9 separated by the isolation structure 4. In this way, the isolation structure 4 including the first isolation part 41 and the second isolation part 42 can make it easier for the light-emitting units 10 to be independently encapsulated, thereby improving encapsulation yield of the display panel.

In some embodiments, the orthographic projection of the first opening 61 on the substrate 1 is located within the orthographic projection of the first isolation part 41 on the substrate 1.

In some embodiments, the orthographic projection of the first opening 61 on the substrate 1 is located within an orthographic projection of a side of the first isolation portion 41 away from the substrate 1 on the substrate 1.

In this way, the first opening 61 is less likely to affect the morphology of the isolation structure 4, thereby improving the overlap effect between the second electrode 9 and the isolation structure 4.

In some embodiments, please refer to FIG. 5 again, a minimum one W of distances between an orthographic projection of a sidewall of the first isolation part 41 on a side of the sidewall facing away from the substrate 1 and edges of an orthographic projection of the side of the first opening 61 facing away from the substrate 1 on the substrate 1 may be greater than 0. For example, the distance W may be 0.2 μm, 0.5 μm, 0.7 μm, 1 μm, 1.3 μm, or 1.5 μm. Reasonably setting the distance W can make the first opening 61 less likely to affect the morphology of the isolation structure 4.

In some embodiments, please refer to FIG. 5 again, the minimum one of distances W between the orthographic projection of the sidewall of the first isolation part 41 on a side of the sidewall facing away from the substrate 1 on the substrate 1 and edges of the orthographic projection of the side of the first opening 61 facing away from the substrate 1 on the substrate 1 may be greater than 1 μm and less than or equal to 10μm. For example, the distance W may be 1 μm, 2 μm, 3 μm, 4 μm, 5 μm, 6 μm, 7 μm, 8 μm, 9 μm, or 10 μm.

As shown in FIG. 23, the second electrode 9 is electrically connected to the first isolation part 41. The first isolation part 41 may include a conductive material, and the second electrode 9 of the light-emitting unit 10 extends to contact the sidewall of the first isolation part 41, so as to achieve electrical connection between the second electrode 9 of the light-emitting unit 10 and the first isolation part 41.

As shown in FIG. 24, the isolation structure 4 may further include a third isolation part 43 located on a side of the first isolation part 41 facing the substrate 1, and the second electrode 9 is electrically connected to the third isolation part 43.

The third isolation part 43 may include a conductive material, and the second electrode 9 of the light-emitting unit 10 extends to contact the sidewall of the third isolation part 43, so as to achieve electrical connection between the second electrode 9 of the light-emitting unit 10 and the third isolation part 43.

Specifically, the third isolation part 43 may include a metal material, such as molybdenum; and/or, the first isolation part 41 may include a conductive material, such as a metal material, for example, aluminum; and/or, the second isolation part 42 may include a conductive material, such as a metal material, for example, titanium. In this way, when the isolation structure 4 separates the material layer for the second electrodes 9 into the second electrodes 9, it makes easier that the second electrodes 9 can be electrically connected to the first isolation part 41 and/or the third isolation part 43.

For example, the orthographic projection of the light-emitting part 8 on the substrate 1 is located outside the orthographic projection of the third isolation part 43 and/or the first isolation part 41 on the substrate 1. In this way, the light-emitting part 8 does not overlap with the isolation structure 4, which can effectively reduce crosstalk between the light-emitting units 10.

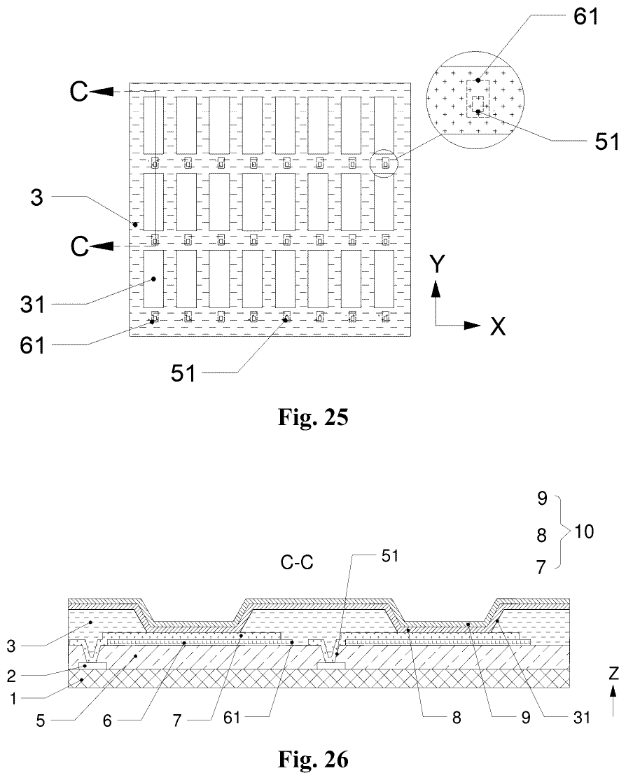

In some possible implementations, please refer to FIGS. 25 and 26, the light-emitting unit 10 may be located on the side of the inorganic layer 6 away from the substrate 1. The light-emitting unit 10 includes a first electrode 7, which is electrically connected to the driver circuit layer 2 through the first opening 61 and the first via 51. For a light-emitting unit 10, the first via 51 corresponding to the first electrode 7 of the light-emitting unit 10 and at least one first opening 61 adjacent to the light-emitting unit 10 are located on a same side of the light-emitting unit 10. In this way, it is beneficial to improve the pixel aperture ratio of the display panel, thereby enhancing the display effect of the display panel.

The inorganic layer 6 plays a function of blocking water vapor. In this embodiment, the inorganic layer 6 is disposed between the light-emitting unit 10 and the insulating layer 5. The inorganic layer 6 not only can block external water vapor from entering the insulating layer 5, but also can block water vapor in the insulating layer 5 from entering the light-emitting material layer for the light-emitting units 10, thereby reducing the risk of dark spots appearing in the light-emitting units 10 due to the water vapor in the insulating layer 5 and improving the display effect of the display panel.

If the inorganic layer 6 completely covers the insulating layer 5, the water vapor in the insulating layer 5 cannot be discharged during subsequent preparation processes of the display panel. When the water vapor in the insulating layer 5 reaches a certain amount, it is easy to cause the inorganic layer 6 to crack, thereby affecting stability of the inorganic layer 6, and accordingly affecting the effect of the inorganic layer 6 in blocking the water vapor in the insulating layer 5 from entering the light-emitting unit 10.

In this embodiment, since the inorganic layer 6 is provide with the first openings 61, the water vapor in the insulating layer 5 can be discharged timely during subsequent preparation processes of the display panel, so as not to easily cause the inorganic layer 6 to crack. Since the orthographic projection of the first opening 61 on the substrate 1 is located outside the orthographic projection of the light-emitting unit 10 on the substrate 1, the vapor discharged from the first opening 61 is less likely to enter the light-emitting units 10, thereby reducing likelihood of dark spots appearing in the light-emitting unit 10.

This embodiment can be combined with some or all of the features in the above embodiments, and will not be repeated here.

The interval D6 between light-emitting regions (corresponding to the pixel openings 31) of adjacent light-emitting units 10 arranged along the first direction Y may be greater than the interval D5 between light-emitting regions (corresponding to the pixel openings 31) of adjacent light-emitting units 10 arranged along the second direction X. The first direction Y and the second direction X intersect with each other, and the orthographic projections of the first opening 61 and the first via 51 on the substrate 1 are located within an orthographic projection of a gap between adjacent light-emitting units 10 arranged along the first direction Y on the substrate 1. By setting that the orthographic projections of the first opening 61 and the first via 51 on the substrate 1 are located within the orthographic projection of the gap between adjacent light-emitting units 10 which have a larger gap on the substrate 1, which is beneficial to improve the pixel aperture ratio of the display panel and thus enhancing the display effect of the display panel.

In some possible embodiments, please refer to FIGS. 23 to 26, etc., the application also provides a display panel, including: a substrate 1, a driver circuit layer 2, an insulation layer 5, an inorganic layer 6, and a plurality of light-emitting units 10.

The driver circuit layer 2 is located on the substrate 1, the insulation layer 5 is located on a side of the driver circuit layer 2 away from the substrate 1, and the insulation layer 5 is provided with a plurality of first via 51 penetrating through the insulation layer 5 along a thickness direction Z of the substrate 1.

The inorganic layer 6 is located on a side of the insulating layer 5 away from substrate 1. An orthographic projection of the inorganic layer 6 on the substrate 1 overlaps at least partially with an orthographic projection of the insulating layer 5 on the substrate 1. The inorganic layer 6 is provided with a plurality of first openings 61 penetrating through the inorganic layer 6 along the thickness direction Z of substrate 1. An orthographic projection of the first opening 61 on the substrate 1 overlaps with an orthographic projection of a first via 51 on the substrate 1. It is not necessary for this embodiment to provide a second via 62. A portion of the first opening 61 can serve as the second via 62. For example, the first opening 61 may communicate with the first via 51.

The light-emitting units 10 are located on a side of the inorganic layer 6 away from the substrate 1. Each of the light-emitting unit 10 includes a first electrode 7, which is electrically connected to the driver circuit layer 2 through the first opening 61 and the first via 51. The orthographic projection of a part of the first opening 61 which has its orthographic projection overlapped with an orthographic projection of the first via 51 on the substrate 1 is located outside an orthographic projection of the first electrode 7 on the substrate 1.

The inorganic layer 6 plays a function of blocking water vapor. In this embodiment, the inorganic layer 6 is disposed between the light-emitting units 10 and the insulating layer 5. The inorganic layer 6 not only can block external water vapor from entering the insulating layer 5, but also can block water vapor in the insulating layer 5 from entering the light-emitting material layer for the light-emitting units 10, thereby reducing the risk of dark spots appearing in the light-emitting units 10 due to the water vapor in the insulating layer 5 and improving the display effect of the display panel.

If the inorganic layer 6 completely covers the insulating layer 5, the water vapor in the insulating layer 5 cannot be discharged during subsequent preparation process of the display panel. When the water vapor in the insulating layer 5 reaches a certain amount, it is easy to cause the inorganic layer 6 to crack, thereby affecting stability of the inorganic layer 6 and accordingly affecting the effect of the inorganic layer 6 in blocking the water vapor in the insulating layer 5 from entering the light-emitting unit 10.

In this embodiment, since the inorganic layer 6 is provided with the first openings 61, the water vapor in the insulating layer 5 can be discharged timely during subsequent preparation processes of the display panel, so as not to easily cause the inorganic layer 6 to crack. Since the orthographic projection of the first opening 61 on the substrate 1 is located outside the orthographic projection of the light-emitting unit 10 on the substrate 1, the vapor discharged from the first opening 61 is less likely to enter the light-emitting unit 10, thereby reducing likelihood of dark spots appearing in the light-emitting unit 10.

This embodiment can be combined with some or all of the features in the above embodiments, and will not be repeated here.

As shown in FIGS. 1 to 26, in some possible embodiments, the application also provides a display panel, including: a substrate 1; an inorganic layer 6 located on a side of substrate 1 and provided with a plurality of first opening 61 penetrating through the inorganic layer 6 along a thickness direction of substrate 1; a pixel defining layer 3 located on a side of the inorganic layer 6 away from the substrate 1, with a plurality of pixel openings 31 being surrounded by the pixel defining layer 3, wherein orthographic projections of-first opening 61 on the substrate 1 and the orthographic projections of the pixel openings on the substrate are offset. In some embodiments, the orthographic projection of the first opening 61 on the substrate 1 is located within an orthographic projection of the pixel defining layer 3 31 on the substrate 1 between adjacent pixel openings.

In this embodiment, the first opening 61 and the pixel openings 31 are offset, so that the first opening 61 does not affect normal light emission of light-emitting units 10 located in the pixel openings 31. The first opening 61 is located within an orthographic projection of the pixel defining layer 3 on the substrate 1 between adjacent pixel openings 31, which can improve the pixel aperture ratio of the display panel and thus enhance the display effect of the display panel.

In some possible implementations, the plurality of first openings 61 communicate with each other to separate the inorganic layer 6 into a plurality body parts 63 which are spaced apart from each other; the display panel may further include a driver circuit layer 2 located on the substrate 1; and a plurality of light-emitting units 10, each of which includes a first electrode 7, the first electrode 7 is electrically connected to the driver circuit layer 2, wherein an orthographic projection of the first electrode 7 on the substrate 1 is located within an orthographic projection of the body part 63 on the substrate 1. In some embodiments, an orthographic projection of a part of the first electrode 7 corresponding to the pixel opening 31 is located within the orthographic projection of the body part 63 on the substrate 1.

In these optional embodiments, the plurality of first openings 61 communicate with each other separate the inorganic layer 6 into block-shaped body parts 63 that are spaced apart from each other, and the orthographic projection of the first electrode 7 on the substrate 1 is located within the orthographic projection of the body part 63 on the substrate 1, so that the body parts 63 can provide protection for the first electrode 7.

In some embodiments, the orthographic projection of the first electrode 7 on the substrate 1 is smaller than the orthographic projection of the body part 63 on the substrate 1, and a minimum one of distances between edges of the orthographic projection of the first electrode 7 on the substrate 1 and edges of the orthographic projection of the body part 63 on the substrate 1 is greater than or equal to 2 μm. In some embodiments, it may be that a minimum one of distances between edges of an orthographic projection of a part of the first electrode 7 corresponding to the pixel opening 31 on the substrate 1 and edges of the orthographic projection of the body part 63 on the substrate 1 is greater than or equal to 2 μm. In this way, the body part 63 may have a large enough distribution area to provide perfect protection for the first electrode 7.

In some possible implementations, the application also provides an electronic device, including: the display panel described in the application, or a display panel prepared by the method for preparing a display panel described in the application. The electronic device may be a device with image processing capabilities, such as a server, a personal computer, a laptop, a mobile phone, a tablet, a wearable device, and an on-board display device, etc. Since the electronic device includes the display panel described in the application, the electronic device has a better display quality.

The various technical features of the above embodiments can be combined arbitrarily. In order to make the description concise, not all possible combinations of the various technical features in the above embodiments have been described. However, as long as there is no contradiction in the combination of these technical features, they should be considered within the scope of the application.

The above embodiments are only several embodiments of the application. Although their descriptions are specific and detailed, they should not be understood as limiting the scope of the application. It should be pointed out that for those skilled in the art, several modifications and improvements can be made without departing from the conception of the application, and all of them are within the scope of the application. Therefore, the scope of the application is only limited by the appended claims.

What is claimed is:

1. A display panel, comprising:
a substrate;
an inorganic layer located on a side of the substrate and provided with a plurality of first openings penetrating through the inorganic layer along a thickness direction of the substrate; and
an isolation structure located on a side of the inorganic layer away from the substrate, with a plurality of isolation openings being surrounded by the isolation structure;
wherein orthographic projections of the plurality of first openings on the substrate are located at least partially within an orthographic projection of the isolation structure on the substrate.

2. The display panel according to claim 1, further comprising:
a driver circuit layer located on the substrate;
an insulation layer located on a side of the driver circuit layer away from the substrate, wherein the inorganic layer is located on a side of the insulation layer away from the substrate, and the insulation layer is provided with a plurality of first vias penetrating through the insulation layer along the thickness direction of the substrate; and
a plurality of light-emitting units, each of which comprises a first electrode, wherein the first electrode is electrically connected to the driver circuit layer through the first via.

3. The display panel according to claim 2, wherein the first via communicates with the first opening, the first electrode is electrically connected to the driver circuit layer through the first opening and the first via, an orthographic projection of the first via on the substrate is located within an orthographic projection of the first opening on the substrate, and an area of an orthographic projection of the first via on the substrate is smaller than an area of the orthographic projection of the first opening on the substrate.

4. The display panel according to claim 3, wherein the orthographic projection of the first opening on the substrate is located partially outside an orthographic projection of the first electrode on the substrate; and
a center of the orthographic projection of the first opening on the substrate is spaced apart from a center of the orthographic projection of the first via on the substrate; or
the orthographic projection of the first opening on the substrate is located within the orthographic projection of the first electrode on the substrate, and the orthographic projection of the first via on the substrate is located within the orthographic projection of the first electrode on the substrate.

5. The display panel according to claim 3, wherein the orthographic projection of the first opening on the substrate comprises a first edge and a second edge arranged opposite to each other, and an orthographic projection of a side of the first via away from the substrate on the substrate comprises a third edge and a fourth edge arranged opposite to each other wherein the first edge, the third edge, the fourth edge and the second edge are arranged in the order, and the third edge is located on a side of the fourth edge away from the light-emitting unit which corresponds to the first via where the third edge and the fourth edge are located,
wherein a minimum distance between the first edge and the third edge is greater than a minimum distance between the second edge and the fourth edge; or
the minimum distance between the first edge and the third edge is greater than or equal to 2 μm and less than or equal to 10 μm; or
the minimum distance between the second edge and the fourth edge is greater than or equal to 0.3 μm and less than or equal to 5 μm.

6. The display panel according to claim 5, wherein the first edge is located outside the orthographic projection of the first electrode on the substrate; or
the second edge is located within the orthographic projection of the first electrode on the substrate; or
at least a portion of edges of the orthographic projection of the first electrode on the substrate is located within the orthographic projection of the first opening on the substrate.

7. The display panel according to claim 6, wherein a minimum distance between an orthographic projection of a part of the first electrode located in the first opening on a side of the part facing the first edge on the substrate and the first edge is greater than or equal to 2 μm and less than or equal to 8 μm.

8. The display panel according to claim 2, wherein an orthographic projection of the first via on the substrate is spaced apart from the orthographic projection of the first opening on the substrate.

9. The display panel according to claim 8, wherein the inorganic layer is provided with a plurality of second vias penetrating the inorganic layer, and the first via communicates with the second via, wherein the orthographic projection of the first electrode on the substrate is located outside the orthographic projection of the first opening on the substrate, and the first electrode is electrically connected to the driver circuit layer sequentially through the second via and the first via.

10. The display panel according to claim 9, wherein a center of an orthographic projection of the second via on the substrate coincides with a center of an orthographic projection of the first via on the substrate.

11. The display panel according to claim 9, wherein for adjacent first via and first opening, a minimum one of distances between edges of an orthographic projection of the first via on the substrate and edges of the orthographic projection of the first opening on the substrate is greater than or equal to 5 μm and less than or equal to 10 μm.

12. The display panel according to claim 2, wherein the isolation structure comprises a first isolation unit and a second isolation unit, wherein a width of an orthographic projection of the first isolation unit on the substrate is greater than a width of an orthographic projection of the second isolation unit on the substrate, wherein the orthographic projection of the first opening on the substrate is located within the orthographic projection of the first isolation unit on the substrate, and the orthographic projection of the first opening on the substrate is located outside the orthographic projection of the second isolation unit on the substrate.

13. The display panel according to claim 12, wherein:
the first isolation unit and the second isolation unit are arranged around a same isolation opening, and the first isolation unit and the second isolation unit are located on different sides of the isolation opening, wherein the first isolation unit extends along a second direction, and the second isolation unit extends along a first direction; or
the first isolation unit and the second isolation unit are arranged around different isolation openings; or
the orthographic projection of the isolation structure on the substrate is in a mesh-like shape, and the first isolation unit is located at an intersection of the isolation structure extending in different directions.

14. The display panel according to claim 13, wherein an extension length of the first isolation unit in the second direction is greater than an extension length of the second isolation unit in the first direction.

15. The display panel according to claim 13, wherein an angle between a line connecting a center of an orthographic projection of the first via on the substrate and a center of the orthographic projection of the first opening on the substrate and the second direction is greater than or equal to 0 degree and less than 90 degree; or
the angle between the line connecting the center of the orthographic projection of the first via on the substrate and the center of the orthographic projection of the first opening on the substrate and the second direction is greater than or equal to 0 degree and less than or equal to 30 degree; or
the angle between the line connecting the center of the orthographic projection of the first via on the substrate and the center of the orthographic projection of the first opening on the substrate and the second direction is equal to 0 degree;
wherein the first direction is perpendicular to the second direction.

16. The display panel according to claim 2, wherein the isolation structure comprises a third isolation unit and a fourth isolation unit, a length of an orthographic projection of the third isolation unit on the substrate is greater than a length of an orthographic projection of the fourth isolation unit on the substrate, wherein the orthographic projection of the first opening on the substrate is located within an orthographic projection of the third isolation unit on the substrate, and the orthographic projection of the first opening on the substrate is located outside an orthographic projection of the fourth isolation unit on the substrate.

17. The display panel according to claim 16, wherein the inorganic layer is further provided with a plurality of second vias penetrating through the inorganic layer along the thickness direction of the substrate, wherein an orthographic projection of the second via on the substrate is located within the orthographic projection of the fourth isolation unit on the substrate, and the orthographic projection of the second via on the substrate overlaps with the orthographic projection of the first via on the substrate.

18. The display panel according to claim 2, wherein the orthographic projection of the first opening on the substrate and an orthographic projection of the first via on the substrate are both located within an orthographic projection of a side of the isolation structure facing the substrate on the substrate,
a minimum one of distances between edges of an orthographic projection of a side of the first opening away from the substrate on the substrate and an orthographic projection of a sidewall of the isolation structure facing the isolation opening on a side of the side wall close to the substrate on the substrate is greater than 0 μm and less than or equal to 10 μm.

19. A display panel according to claim 2, wherein the display panel comprises a display area and a non-display area, and further comprises a pixel defining layer located between the inorganic layer and the isolation structure, the orthographic projection of the isolation structure on the substrate is located within an orthographic projection of the pixel defining layer on the substrate, the pixel defining layer further extends to the non-display area, the pixel defining layer defines a plurality of pixel openings in the display area, and the pixel openings communicate with the isolation openings, wherein at least a portion of the light-emitting units are located within the pixel openings, and the orthographic projection the first opening on the substrate is offset from an orthographic projection of the pixel opening on the substrate.

20. The display panel according to claim 19, wherein the pixel defining layer located in the non-display area is provided with a plurality of third openings penetrating through the pixel defining layer along the thickness direction of the substrate, the inorganic layer extends from the display area to the non-display area, and an orthographic projection of the inorganic layer on the substrate covers orthographic projections of the third openings on the substrate.

21. The display panel according to claim 1, wherein:
an orthographic projection of the inorganic layer on the substrate is in a mesh-like shape, and the plurality of first openings are spaced apart from each other; or
the plurality of first openings communicate with each other to separate the inorganic layer into a plurality of body parts spaced apart from each other.

22. A display panel according to claim 1, wherein the display panel includes a display area, the plurality of first openings are located in the display area, and a ratio of a sum of areas of the orthographic projections of the first openings on the substrate to an area of the display area is 5% to 20%; or
the isolation structure comprises a recessed part which is formed on a surface of the isolation structure away from the substrate and recessed towards the substrate, wherein an orthographic projection of the recessed part on the substrate overlaps at least partially with the orthographic projection of the first opening on the substrate.

23. The display panel according to claim 1, wherein the isolation structure comprises a first isolation part and a second isolation part stacked in a direction away from the substrate, wherein the second isolation part protrudes towards the isolation opening relative to the first isolation part, and the orthographic projection of the first opening on the substrate is located within an orthographic projection of the first isolation part on the substrate,
wherein the first isolation part comprises a first surface facing the substrate and a second surface facing away from the substrate, wherein a minimum one of distances between edges of a smaller one of orthographic projections of the first surface and the second surface on the substrate and edges of the orthographic projection of the first opening on the substrate is greater than or equal to 1 μm.

24. The display panel according to claim 2, wherein the display panel further comprises a plurality of signal traces, wherein an orthographic projection of the signal trace on the substrate overlaps at least partially with the orthographic projection of the first opening on the substrate, and
the display panel comprises a touch electrode, and the touch electrode comprises a plurality of touch traces, wherein the signal traces comprise the touch traces; or
the substrate comprises a plurality of array traces, and the signal traces comprise the array traces.

25. The display panel according to claim 24, wherein an extension direction of the signal trace intersects with an extension direction of the first opening; or
a line width of the touch trace is smaller than a width of the first opening.

26. A display panel comprising:
a substrate;
an inorganic layer located on a side of the substrate and provided with a plurality of first opening penetrating through the inorganic layer along a thickness direction of the substrate; and
a pixel defining layer located on a side of the inorganic layer away from the substrate, with a plurality of pixel openings being surrounded by the pixel defining layer,
wherein orthographic projections of the first openings on the substrate and orthographic projections of the pixel openings on the substrate are offset.

27. The display panel according to claim 26, wherein:
the plurality of first openings communicate with each other to separate the inorganic layer into a plurality of body parts spaced apart from each other;
the display panel further comprises:
a driver circuit layer located on the substrate; and
a plurality of light-emitting units, each of which comprises a first electrode, the first electrode is electrically connected to the driver circuit layer,
wherein an orthographic projection of the first electrode on the substrate is located within an orthographic projection of the body part on the substrate.

28. The display panel according to claim 27, wherein an area of the orthographic projection of the first electrode on the substrate is smaller than an area of the orthographic projection of the body part on the substrate, and a minimum one of distances between edges of the orthographic projection of the first electrode on the substrate and edges of the orthographic projection of the body part on the substrate is greater than or equal to 2 μm.

29. An electronic device comprising the display panel according to claim 1.
